(19) United States
(12) Patent Application Publication
(10) Pub. No.: US 2026/0059760 A1
(43) Pub. Date: Feb. 26, 2026

(54) SEMICONDUCTOR DEVICE

(71) Applicant: Kioxia Corporation, Tokyo (JP)

(72) Inventor: Kazumi WATANABE, Yokkaichi Mie (JP)

(21) Appl. No.: 19/069,104

(22) Filed: Mar. 3, 2025

(30) Foreign Application Priority Data
Aug. 23, 2024 (JP) 2024-143386

(51) Int. Cl. H10B 43/40; H01L 23/00; H01L 25/065; H01L 25/18; H10B 41/10; H10B 41/27; H10B 41/41; H10B 43/10; H10B 43/27; H10B 80/00

(52) U.S. Cl. CPC H10B 43/40; H01L 24/08; H01L 25/0657; H01L 25/18; H10B 41/10; H10B 41/27; H10B 41/41; H10B 43/10; H10B 43/27; H10B 80/00; H01L 2224/08145; H01L 2924/1431; H01L 2924/14511

(57) ABSTRACT

A semiconductor device includes a substrate, a first contact electrode connected to the substrate, a second contact electrode separated from the first electrode and connected to the substrate, a gate electrode facing the substrate between the first and second contact electrodes, a third contact electrode on the gate electrode, a first electrode member facing the substrate between the first contact electrode and the gate electrode, and a second electrode member facing the substrate between the second contact electrode and the gate electrode. The gate electrode contains a first conductivity type impurity. The first and second electrode members contain the first conductivity type impurity or a second conductivity type impurity. A concentration of the first or the second conductivity type impurity in the first and second electrode members is lower than a concentration of the first conductivity type impurity in the gate electrode.

### CROSS-REFERENCE TO RELATED APPLICATION

This application is based upon and claims the benefit of priority from Japanese Patent Application No. 2024-143386, filed Aug. 23, 2024, the entire contents of which are incorporated herein by reference.

### FIELD

Embodiments described herein relate generally to a semiconductor device.

### BACKGROUND

A semiconductor device including a semiconductor substrate, a first contact electrode connected to the semiconductor substrate, a second contact electrode separated from the first contact electrode in a first direction and connected to the semiconductor substrate, and an electrode provided between the first contact electrode and the second contact electrode and facing the semiconductor substrate is known.

### BRIEF DESCRIPTION OF THE DRAWINGS

FIG. 1 is a schematic circuit diagram illustrating a configuration of a part of a memory die.

FIG. 2 is a schematic circuit diagram illustrating a configuration of a part of a peripheral circuit.

FIG. 3 is a schematic circuit diagram illustrating a configuration of a part of the peripheral circuit.

FIG. 4 is a schematic exploded perspective view illustrating a configuration of a semiconductor storage device according to a first embodiment.

FIG. 5 is a schematic bottom view illustrating a configuration example of a chip.

FIG. 6 is a schematic cross-sectional view illustrating a configuration of a part of the memory die.

FIG. 7 is a schematic cross-sectional view illustrating a configuration of a part of the memory die.

FIG. 8 is a schematic bottom view illustrating a configuration of a part of the chip.

FIG. 9 is a schematic cross-sectional view illustrating a configuration of a part of the chip.

FIG. 10 is a schematic plan view illustrating a structure of a word line switch according to the first embodiment.

FIG. 11 is a schematic cross-sectional view illustrating a structure of a word line switch cut along a dotted line A-A′ in FIG. 10.

FIG. 12 is a schematic cross-sectional view illustrating a structure of the word line switch cut along a dotted line B-B′ in FIG. 10.

FIG. 13 is a schematic cross-sectional view illustrating a method of manufacturing a high-voltage transistor among transistors according to the first embodiment.

FIG. 14 is a schematic cross-sectional view illustrating the manufacturing method.

FIG. 15 is a schematic cross-sectional view illustrating the manufacturing method.

FIG. 16 is a schematic cross-sectional view illustrating the manufacturing method.

FIG. 17 is a schematic cross-sectional view illustrating the manufacturing method.

FIG. 18 is a schematic cross-sectional view illustrating the manufacturing method.

FIG. 19 is a schematic cross-sectional view illustrating the manufacturing method,

FIG. 20 is a schematic cross-sectional view illustrating the manufacturing method.

FIG. 21 is a schematic cross-sectional view illustrating the manufacturing method.

FIG. 22 is a schematic cross-sectional view illustrating the manufacturing method.

FIG. 23 is a schematic cross-sectional view illustrating the manufacturing method.

FIG. 24 is a schematic cross-sectional view illustrating the manufacturing method.

FIG. 25 is a schematic plan view illustrating a structure of a transistor according to a first comparative example.

FIG. 26 is a schematic cross-sectional view illustrating a structure of the transistor cut along a dotted line CC′ in FIG. 25.

FIG. 27 is a schematic plan view illustrating a structure of a transistor according to a second comparative example.

FIG. 28 is a schematic plan view illustrating a structure of a transistor according to a modification example of the first embodiment.

FIG. 29 is a schematic cross-sectional view illustrating a structure of the transistor cut along a dotted line D-D′ in FIG. 28.

FIG. 30 is a schematic cross-sectional view illustrating a structure of the transistor cut along a dotted line E-E′ in FIG. 28.

FIG. 31 is a schematic plan view illustrating a structure of a transistor according to a second embodiment.

FIG. 32 is a schematic cross-sectional view illustrating a structure of the transistor cut along a dotted line F-F′ in FIG. 31.

### DETAILED DESCRIPTION

Embodiments provide a semiconductor device that appropriately operates.

In general, according to one embodiment, a semiconductor device comprises a semiconductor substrate; a first contact electrode connected to the semiconductor substrate; a second contact electrode separated from the first contact electrode and connected to the semiconductor substrate; a gate electrode facing the semiconductor substrate between the first and second contact electrodes; a third contact electrode on the gate electrode; a first electrode member facing the semiconductor substrate between the first contact electrode and the gate electrode; and a second electrode member facing the semiconductor substrate between the second contact electrode and the gate electrode. The gate electrode contains a first conductivity type impurity. Each of the first and second electrode members contains the first conductivity type impurity or a second conductivity type impurity that is different from the first conductivity type impurity. A concentration of the first conductivity type impurity or the second conductivity type impurity in the first and second electrode members is lower than a concentration of the first conductivity type impurity in the gate electrode.

Next, embodiments of this disclosure will be described in detail with reference to the accompanying drawings. The embodiments described below are merely examples, and are not intended to limit the present disclosure. In the drawings, some parts may be omitted for description. Parts common to a plurality of embodiments are represented by the same reference numerals and signs, and descriptions thereof may not be repeated.

In the present specification, the term “semiconductor device” may mean a semiconductor storage device or another semiconductor device. The semiconductor storage device may mean a memory die, or a memory system including a controller die, such as a memory chip, a memory card, or a solid state drive (SSD). The semiconductor storage device may mean a configuration including a host computer, such as a smartphone, a tablet terminal, or a personal computer.

In the present specification, when a first configuration is “electrically connected” to a second configuration, the term “electrically connected” may mean that a first configuration is directly connected to a second configuration, or that a first configuration is connected to a second configuration via a wiring, a semiconductor member, a transistor, or the like. For example, when three transistors are connected in series, even when the second transistor is in an OFF state, the first transistor is “electrically connected” to the third transistor.

In the present specification, when a first configuration is “connected between” a second configuration and a third configuration, the term “connected between” may mean that the first configuration, the second configuration, and the third configuration are connected in series, or that the second configuration is connected to the third configuration via the first configuration.

In the present specification, when a circuit or the like “conducts” two wirings or the like, the term “conduct” may mean that the circuit or the like includes a transistor or the like, the transistor or the like is provided in a current path between the two wirings, and the transistor or the like is in an ON state.

In the present specification, a predetermined direction parallel to an upper surface of a substrate is referred to as an X direction. A direction parallel to the upper surface of the substrate and perpendicular to the X direction is referred to as a Y direction. A direction perpendicular to the upper surface of the substrate is referred to as a Z direction.

In the present specification, a direction along a predetermined surface may be referred to as a first direction. A direction intersecting the first direction along the predetermined surface may be referred to as a second direction. A direction intersecting the predetermined surface may be referred to as a third direction. Each of the first direction, the second direction, and the third direction may correspond to any of the X direction, the Y direction, and the Z direction, or may not correspond to any of the X direction, the Y direction, and the Z direction.

In the present specification, the terms “width”, “length”, “thickness”, or the like of a component, a member, or the like in a predetermined direction may mean a width, a length, a thickness, or the like in a cross section or the like observed by scanning electron microscopy (SEM) or transmission electron microscopy (TEM).

### First Embodiment

### Circuit Configuration of Memory Die MD

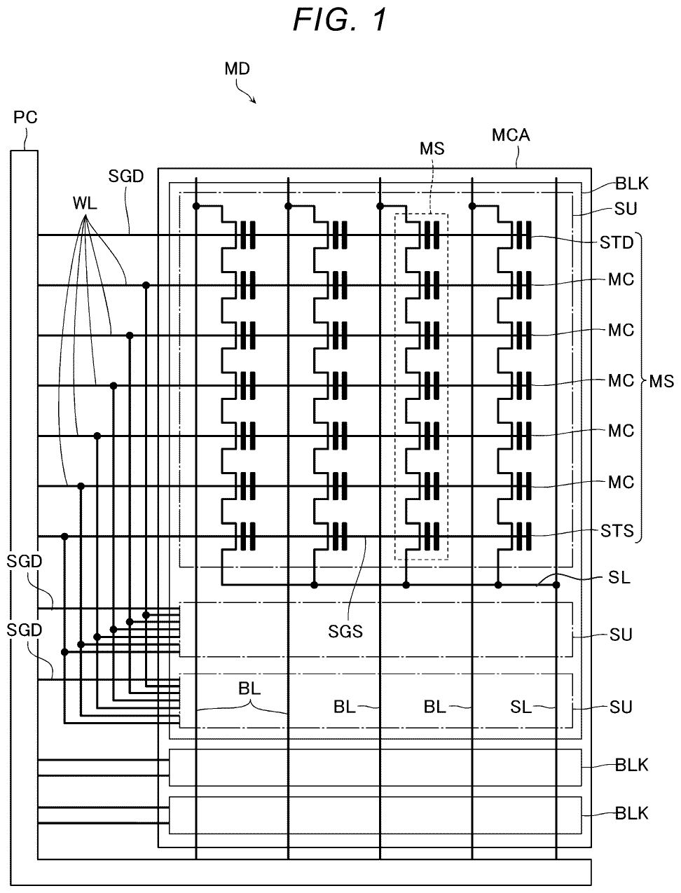

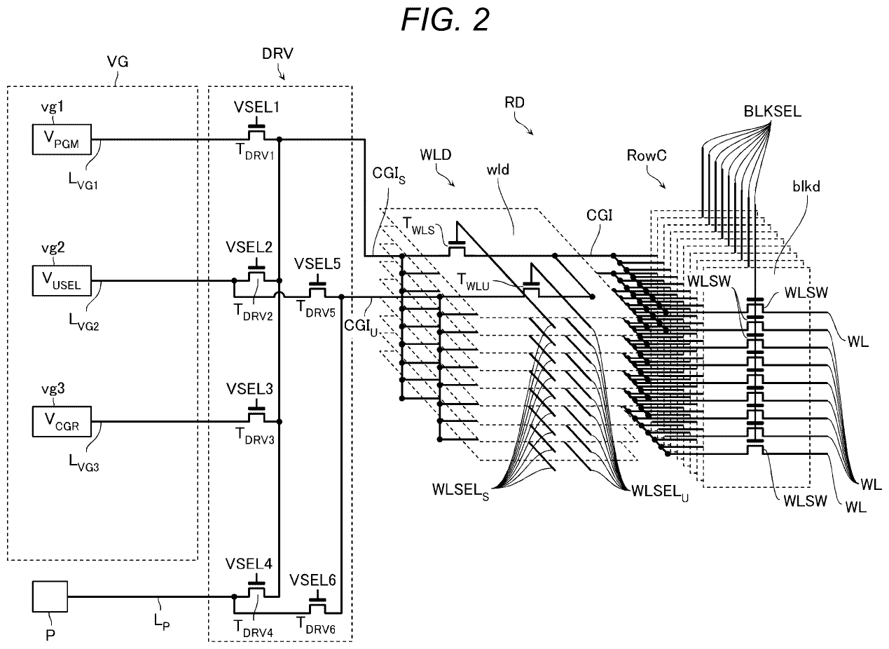

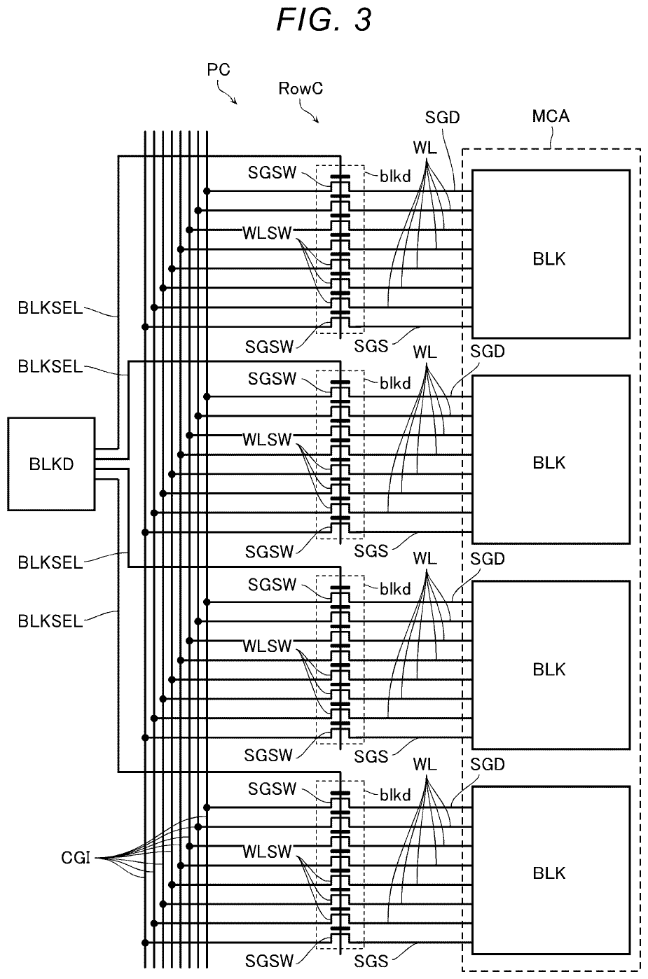

FIG. 1 is a schematic circuit diagram illustrating a part of a configuration of a memory die MD according to a first embodiment. FIGS. 2 and 3 are schematic circuit diagrams illustrating a part of a configuration of a peripheral circuit PC.

As shown in FIG. 1, the memory die MD includes a memory cell array MCA and the peripheral circuit PC. As shown in FIG. 2, the peripheral circuit PC includes a voltage generating circuit VG and a row decoder RD.

### Circuit Configuration of Memory Cell Array MCA

As shown in FIG. 1, the memory cell array MCA includes a plurality of memory blocks BLK. Each of the plurality of memory blocks BLK includes a plurality of string units SU. Each of the plurality of string units SU includes a plurality of memory strings MS. One end of each of the plurality of memory strings MS is connected to the peripheral circuit PC via a bit line BL. The other end of each of the plurality of memory strings MS is connected to the peripheral circuit PC via a common source line SL.

The memory string MS includes a drain-side select transistor STD, a plurality of memory cells MC (i.e., memory transistors), and a source-side select transistor STS. The drain-side select transistor STD, the plurality of memory cells MC, and the source-side select transistor STS are connected in series between the bit line BL and the source line SL. Hereinafter, the drain-side select transistor STD and the source-side select transistor STS may be simply referred to as select transistors STD and STS.

The memory cell MC is a field effect transistor. The memory cell MC includes a semiconductor layer, a gate insulating film, and a gate electrode. The semiconductor layer functions as a channel region. The gate insulating film includes a charge storage film. A threshold voltage of the memory cell MC changes according to an amount of charge in the charge storage film. The memory cell MC stores one bit or a plurality of bits of data. Word lines WL are connected to each of the gate electrodes of the memory cells MC corresponding to one memory string MS. Each of the word lines WL is connected in common to all memory strings MS in one memory block BLK.

The select transistors STD and STS are field effect transistors. Each of the select transistors STD and STS includes a semiconductor layer, a gate insulating film, and a gate electrode. The semiconductor layer functions as a channel region. The gate insulating film may include a charge storage film. A drain-side select gate line SGD is connected to the gate electrode of the drain-side select transistor STD. A source-side select gate line SGS is connected to the gate electrode of the source-side select transistor STS. One drain-side select gate line SGD is connected in common to all memory strings MS in one string unit SU. One source-side select gate line SGS is connected in common to all memory strings MS in one memory block BLK.

### Circuit Configuration of Voltage Generation Circuit VG

For example, as shown in FIG. 2, the voltage generation circuit VG includes a plurality of voltage generation units vg1 to vg3. The voltage generation units vg1 to vg3 generate voltages having predetermined magnitudes and output the voltages via voltage supply lines LVG1 to LVG3 in a read operation, a write operation, and an erase operation. For example, the voltage generation unit vg1 outputs a program voltage VPGM in the write operation. The voltage generation unit vg2 outputs a read pass voltage in the read operation. The voltage generation unit vg2 outputs a write pass voltage in the write operation. The voltage generation unit vg3 outputs a read voltage in the read operation. The voltage generation unit vg3 outputs a verification voltage in the write operation. The voltage generation units vg1 to vg3 may be, for example, a boost circuit such as a charge pump circuit, or a step-down circuit such as a regulator. Each of the step-down circuit and the boost circuit is connected to a voltage supply line LP. A power supply voltage VCC or a ground voltage VSS is applied to the voltage supply line LP. The voltage supply lines LP are connected to, for example, a pad electrode P. Operation voltages output from the voltage generation circuit VG are appropriately adjusted according to control signals from a sequencer.

FIG. 2 shows a configuration example of the voltage generation circuit VG for generating a program voltage, a read pass voltage, a write pass voltage, a read voltage, and a verification voltage to be applied to the word lines WL via a wiring CGI. However, although not shown in the drawing, the voltage generation circuit VG includes a configuration in which a plurality of operation voltages to be applied to the bit lines BL, the source lines SL, and the select gate lines SGD and SGS during the read operation, the write operation, and the erase operation for the memory cell array MCA are generated in addition to operation voltages to be applied to the word lines WL, and the operation voltages are output to a plurality of voltage supply lines. The operation voltages are appropriately adjusted according to control signals from a sequencer not shown in the drawing.

### Circuit Configuration of Row Decoder RD

For example, as shown in FIG. 2, the row decoder RD includes a row control circuit RowC, a word line decoder WLD, and a driver circuit DRV. For example, as shown in FIG. 3, the row decoder RD includes a block decoder BLKD.

For example, as shown in FIG. 3, the row control circuit RowC includes a plurality of block decoder units blkd. The plurality of block decoder units blkd correspond to the plurality of memory blocks BLK in the memory cell array MCA. The block decoder unit blkd includes a plurality of word line switches WLSW and a plurality of select gate line switches SGSW. The plurality of word line switches WLSW are provided corresponding to the plurality of word lines WL in the memory block BLK. The plurality of select gate line switches SGSW are provided corresponding to the drain-side select gate line SGD and the source-side select gate line SGS in the memory block BLK.

The word line switch WLSW and the select gate line switch SGSW are, for example, field effect NMOS transistors. For example, as shown in FIG. 3, a drain electrode of the word line switch WLSW is connected to the word line WL. A drain electrode of the select gate line switch SGSW is connected to the drain-side select gate line SGD or the source-side select gate line SGS. Source electrodes of the word line switch WLSW and the select gate line switch SGSW are connected to the wiring CGI. The wiring CGI is connected to all block decoder units blkd in the row control circuit RowC. Gate electrodes of the word line switch WLSW and the select gate line switch SGSW are connected to a signal supply line BLKSEL. A plurality of signal supply lines BLKSEL are provided corresponding to all block decoder units blkd. The signal supply line BLKSEL is connected to all of the word line switches WLSW and the select gate line switches SGSW in the corresponding block decoder unit blkd.

As shown in FIG. 2, the word line decoder WLD includes a plurality of word line decoder units wld. The plurality of word line decoder units wld are provided corresponding to the plurality of memory cells MC in the memory string MS. In the example of FIG. 2, the word line decoder unit wld includes two transistors TWLS and TWLU. The transistors TWLS and TWLU are, for example, field effect NMOS transistors. Drain electrodes of the transistors TWLS and TWLU are connected to the wiring CGI. A source electrode of the transistor TWLS is connected to a wiring CGIS. A source electrode of the transistor TWLU is connected to a wiring CGIU. A gate electrode of the transistor TWLS is connected to a signal line WLSELS. A gate electrode of the transistor TWLU is connected to a signal line WLSELU. A plurality of signal lines WLSELS are provided corresponding to one of the transistors TWLS in all word line decoder units wld. A plurality of signal lines WLSELU are provided corresponding to the other transistors TWLU in all word line decoder units wld.

As shown in FIG. 2, the driver circuit DRV includes, for example, six transistors TDRV1 to TDRV6. The transistors TDRV1 to TDRV6 are, for example, field effect NMOS transistors. Drain electrodes of the transistors TDRV1 to TDRV4 are connected to the wiring CGIS. Drain electrodes of the transistors TDRV5 and TDRV6 are connected to the wiring CGIU. A source electrode of the transistor TDRV1 is connected to an output terminal of the voltage generation unit vg1 via the voltage supply line LVG1. Source electrodes of the transistors TDRV2 and TDRV5 are connected to an output terminal of the voltage generation unit vg2 via the voltage supply line LVG2. A source electrode of the transistor TDRV3 is connected to an output terminal of the voltage generation unit vg3 via the voltage supply line LVG3. Source electrodes of the transistors TDRV4 and TDRV6 are connected to the pad electrode P via the voltage supply line LP. Each of gate electrodes of the transistors TDRV1 to TDRV6 are connected to each of signal lines VSEL1 to VSEL6.

The block decoder BLKD decodes a block address, applies a voltage in an H state to one signal supply line BLKSEL corresponding to the block address, and applies a voltage in an L state to other signal supply lines BLKSEL.

In the example of FIG. 2, the row decoder RD is provided with the block decoder units blkd each corresponding to one memory block BLK. However, the configuration may be appropriately changed. For example, one block decoder unit blkd may be provided for two or more memory blocks BLK.

### Structure of Memory Die MD

FIG. 4 is a schematic exploded perspective view illustrating a configuration of the semiconductor device according to the first embodiment. As shown in FIG. 4, the memory die MD includes a chip CM on the memory cell array MCA side and a chip CP on the peripheral circuit PC side.

A plurality of external pad electrodes PX that can be connected to bonding wires not shown in the drawing is provided on an upper surface of the chip CM. A plurality of bonding electrodes PI1 are provided on a lower surface of the chip CM. A plurality of bonding electrodes PI2 are provided on an upper surface of the chip CP. Hereinafter, a surface of the chip CM on which the plurality of bonding electrodes PI1 are provided is referred to as a front surface, and a surface of the chip CM on which the plurality of external pad electrodes PX are provided is referred to as a rear surface. A surface of the chip CP on which the plurality of bonding electrodes PI2 are provided is referred to as a front surface, and a surface of the chip CP opposite to the front surface is referred to as a rear surface. In the illustrated example, the front surface of the chip CP is provided above the rear surface of the chip CP, and the rear surface of the chip CM is provided above the front surface of the chip CM.

The chip CM and the chip CP are disposed such that the front surface of the chip CM faces the front surface of the chip CP. The plurality of bonding electrodes PI1 are provided corresponding to the plurality of bonding electrodes PI2, respectively. The bonding electrodes PI1 are positioned to be bondable with the plurality of bonding electrodes PI2. The bonding electrodes PI1 and the bonding electrodes PI2 function as bonding electrodes for bonding and electrically conducting the chip CM and the chip CP.

In the example of FIG. 4, corners a1, a2, a3, and a4 of the chip CM respectively correspond to corners b1, b2, b3, and b4 of the chip CP.

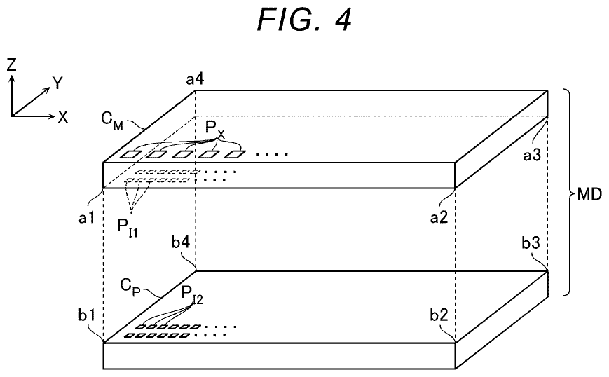

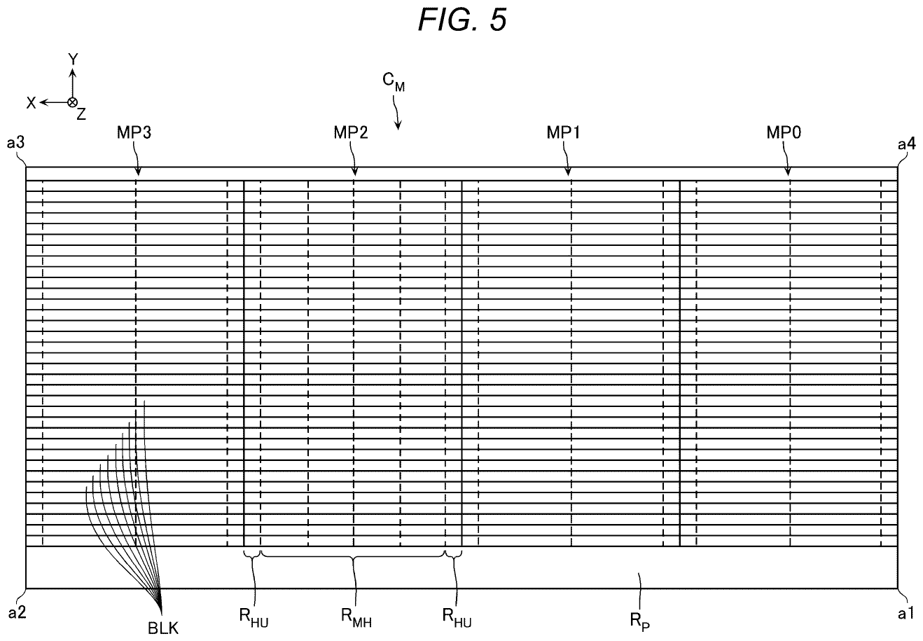

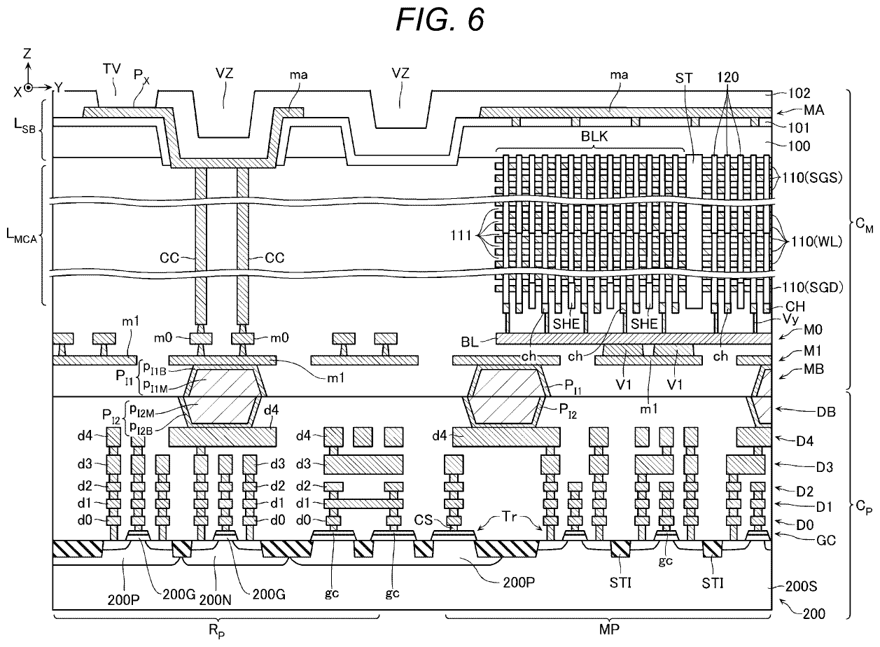

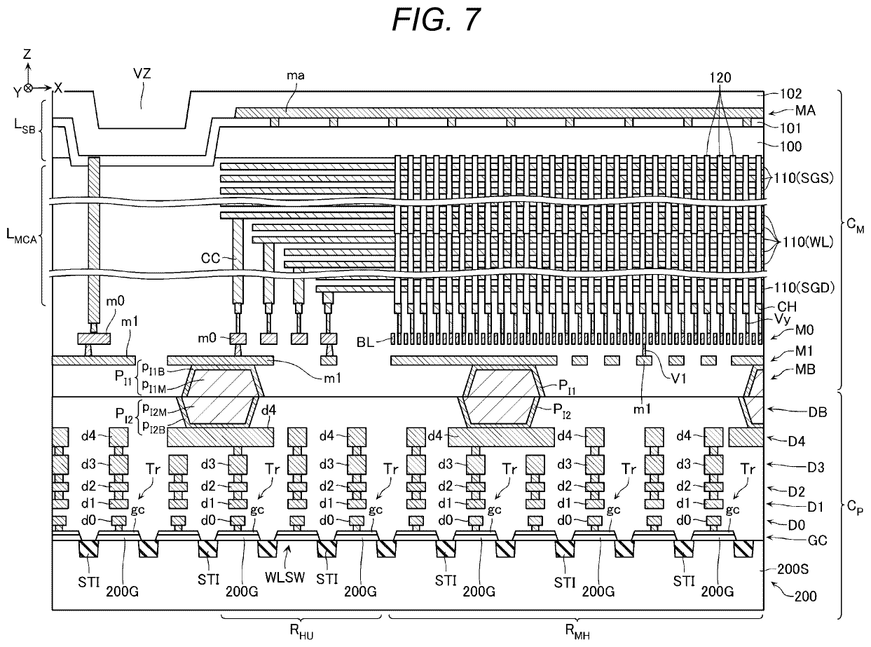

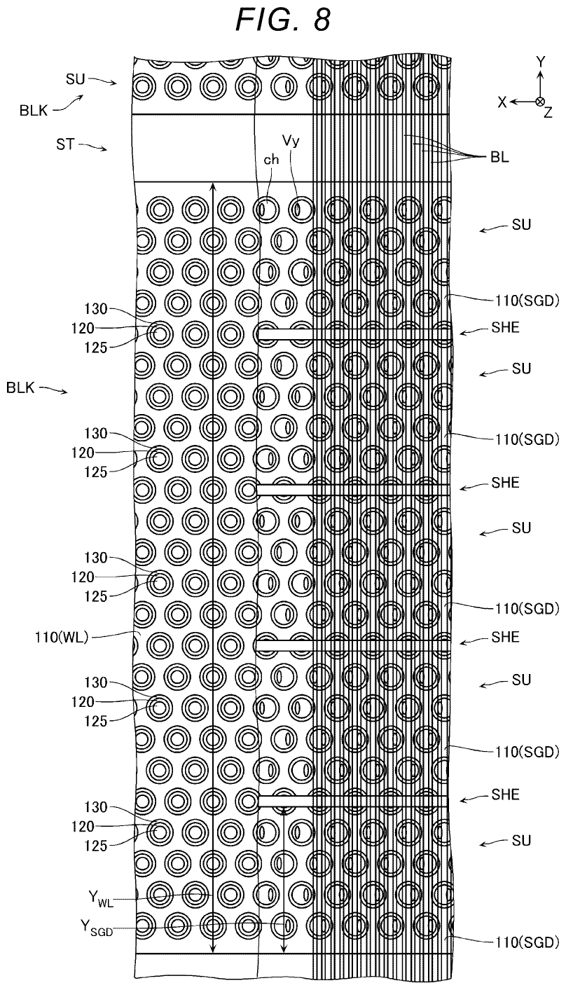

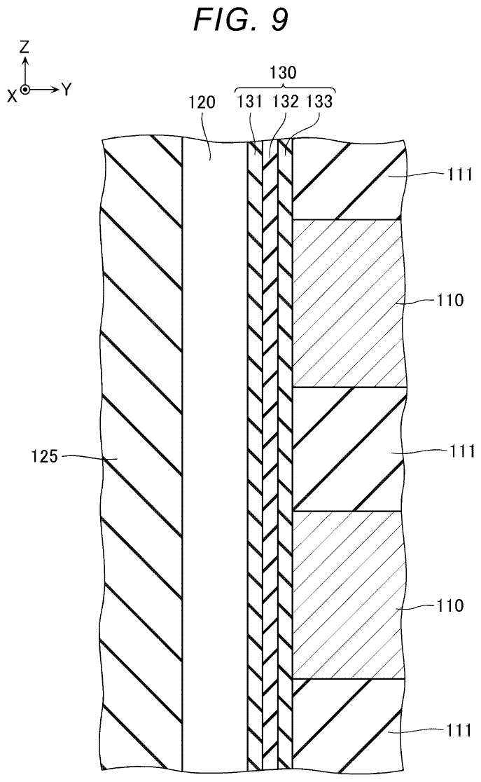

FIG. 5 is a schematic bottom view illustrating a configuration example of the chip CM. In FIG. 5, a part of the configuration such as the bonding electrode PI1 is omitted. FIGS. 6 and 7 are schematic cross-sectional views illustrating a part of the configuration of the memory die MD. FIG. 8 is a schematic bottom view illustrating a part of the configuration of the chip CM. A left region of FIG. 8 shows an XY cross section at a height position corresponding to the word line WL. A right region of FIG. 8 shows an XY cross section at a height position corresponding to the drain-side select gate line SGD. In the right region of FIG. 8, contact electrodes ch and Vy and the bit lines BL are also illustrated to show connection portions between a semiconductor layer 120 and the bit lines BL. Although not shown in the drawing, the contact electrodes ch and Vy, and the bit lines BL are also provided in the left region of FIG. 8. FIG. 9 is a schematic cross-sectional view illustrating a part of the configuration of the chip CM. Although FIG. 9 shows a YZ cross section, a structure similar to the structure of FIG. 9 is observed also in a cross section other than the YZ cross section along the central axis of the semiconductor layer 120 (for example, an XZ cross section).

### Structure of Chip CM

In the example of FIG. 5, the chip CM includes four memory planes MP0 to MP3 arranged in the X direction. Hereinafter, the four memory planes MP0 to MP3 may be simply referred to as memory planes MP. Each of the four memory planes MP0 to MP3 includes a plurality of memory blocks BLK arranged in the Y direction. In the example of FIG. 5, each of the four memory planes MP0 to MP3 includes hook-up regions RHU provided at both end portions in the X direction, and a memory hole region RMH provided therebetween. The chip CM includes a peripheral region RP provided closer to one end side in the Y direction than the four memory planes MP0 to MP3.

In the illustrated example, the hook-up regions RHU are provided at both end portions in the X direction of the memory plane MP. However, such a configuration is merely an example and may be appropriately modified. For example, the hook-up region RHU may be provided not at both end portions in the X direction but at one end portion in the X direction of the memory plane MP. The hook-up region RHU may be provided at the center position or at a position near the center of the memory plane MP in the X direction.

For example, as shown in FIG. 6, the chip CM includes a base layer LSB, a memory cell array layer LMCA provided under the base layer LSB, a contact electrode layer CH provided under the memory cell array layer LMCA, a plurality of wiring layers M0 and M1 provided under the contact electrode layer CH, and a chip bonding electrode layer MB provided under the wiring layers M0 and M1.

### Structure of Base Layer LSB of Chip CM

As shown in FIG. 6, the base layer LSB includes a conductive layer 100 provided on an upper surface of the memory cell array layer LMCA, an insulating layer 101 provided on an upper surface of the conductive layer 100, a rear surface wiring layer MA provided on an upper surface of the insulating layer 101, and an insulating layer 102 provided on an upper surface of the rear surface wiring layer MA.

The conductive layer 100 may include a semiconductor layer such as silicon (Si) doped with an N-type impurity such as phosphorus (P) or a P-type impurity such as boron (B), may include metal such as tungsten (W), and may include a silicide such as tungsten silicide (WSi).

The conductive layer 100 functions as a part of the source line SL shown in FIG. 1. Four conductive layers 100 are provided corresponding to the four memory planes MP0 to MP3 shown in FIG. 5. A region VZ not including the conductive layer 100 is provided at end portions of the memory plane MP in the X direction and the Y direction.

The insulating layer 101 includes, for example, silicon oxide (SiO2) or the like.

The rear surface wiring layer MA includes a plurality of wirings ma. The plurality of wirings ma may contain, for example, aluminum (Al) or the like.

Some of the plurality of wirings ma function as a part of the source line SL shown in FIG. 1. Four wirings ma are provided corresponding to the four memory planes MP0 to MP3 shown in FIG. 5. Each of the wirings ma is electrically connected to the conductive layer 100.

A part of the plurality of wirings ma functions as the external pad electrodes PX shown in FIG. 4. The wiring ma is provided in the peripheral region RP shown in FIG. 5. The wiring ma is connected to contact electrodes CC in the memory cell array layer LMCA in the region VZ not including the conductive layer 100 shown in FIG. 6. A part of the wiring ma is exposed to the outside of the memory die MD via an opening TV provided in the insulating layer 102.

The insulating layer 102 is a passivation layer made of an insulating material such as polyimide.

### Structure of Memory Hole Region RMH of Memory Cell Array Layer LMCA of Chip CM

As described with reference to FIG. 5, the memory cell array layer LMCA is provided with the plurality of memory blocks BLK arranged in the Y direction. As shown in FIG. 6, an inter-block insulating layer ST made of silicon oxide (SiO2) or the like is provided between two memory blocks BLK adjacent to each other in the Y direction.

For example, as shown in FIG. 6, the memory block BLK includes a plurality of conductive layers 110 arranged in the Z direction and a plurality of semiconductor layers 120 extending in the Z direction. As shown in FIG. 9, a gate insulating film 130 is provided between each of the plurality of conductive layers 110 and each of the plurality of semiconductor layers 120.

The conductive layer 110 has a substantially plate-like shape extending in the X direction. The conductive layer 110 may include a stacked film of a barrier conductive film and a metal film, and the like. The barrier conductive film is made of titanium nitride (TiN) or the like. The metal film is made of tungsten (W), molybdenum (Mo), or the like. The conductive layer 110 may contain polycrystalline silicon containing impurities such as phosphorus (P) or boron (B). Interlayer insulating layers 111 made of silicon oxide (SiO2) or the like are provided between the plurality of conductive layers 110 arranged in the Z direction.

Among the plurality of conductive layers 110, one or a plurality of conductive layers 110 located in the uppermost layer function as the gate electrode of the source-side select transistor STS shown in FIG. 1 and the source-side select gate line SGS (refer to FIG. 6). The plurality of conductive layers 110 are electrically independent per memory block BLK.

The plurality of conductive layers 110 located further below function as the gate electrodes of the memory cells MC shown in FIG. 1 and the word lines WL. The plurality of conductive layers 110 are each electrically independent per memory block BLK.

One or a plurality of conductive layers 110 further below function as the gate electrodes of the drain-side select transistors STD shown in FIG. 1 and the drain-side select gate lines SGD. For example, as shown in FIG. 8, a Y-direction width YSGD of the plurality of conductive layers 110 is smaller than a Y-direction width YWL of the conductive layers 110 functioning as the word line WL. An inter-string-unit insulating layer SHE made of silicon oxide (SiO2) or the like is provided between the two conductive layers 110 adjacent in the Y direction.

For example, as shown in FIG. 8, the semiconductor layers 120 are arranged in a predetermined pattern in the X direction and the Y direction. Each of the semiconductor layers 120 functions as a channel region of the plurality of memory cells MC and the select transistors STD and STS in one memory string MS shown in FIG. 1. The semiconductor layer 120 contains, for example, polycrystalline silicon (Si) or the like. The semiconductor layer 120 has a substantially cylindrical shape, and an insulating layer 125 such as silicon oxide is provided in a center portion thereof. Outer peripheral surfaces of the semiconductor layers 120 are surrounded by the plurality of conductive layers 110 with the gate insulating films 130 interposed therebetween, and face the plurality of conductive layers 110.

An impurity region not shown in the drawing is provided at an upper end of the semiconductor layer 120. The impurity region is connected to the conductive layer 100 (refer to FIG. 6). The impurity region contains, for example, an N-type impurity such as phosphorus (P) or a P-type impurity such as boron (B).

An impurity region not shown in the drawing is provided at a lower end of the semiconductor layer 120. The impurity region is connected to the bit line BL via the contact electrode ch and the contact electrode Vy. The impurity region contains, for example, an N-type impurity such as phosphorus (P).

For example, as shown in FIG. 8, the gate insulating film 130 has a substantially cylindrical shape covering the outer circumferential surface of the semiconductor layer 120. For example, as shown in FIG. 9, the gate insulating film 130 includes a tunnel insulating film 131, a charge storage film 132, and a block insulating film 133 stacked between the semiconductor layer 120 and the conductive layer 110. The tunnel insulating film 131 and the block insulating film 133 contain, for example, silicon oxide (SiO2), silicon oxynitride (SiON), or the like. The charge storage film 132 includes, for example, a film such as silicon nitride (SiN) capable of storing charges. The tunnel insulating film 131, the charge storage film 132, and the block insulating film 133 have a substantially cylindrical shape and extend in the Z direction along the outer peripheral surface of the semiconductor layer 120 except for a contact portion between the semiconductor layer 120 and the conductive layer 100.

FIG. 9 shows an example in which the gate insulating film 130 includes the charge storage film 132 such as silicon nitride. However, the gate insulating film 130 may include, for example, a floating gate such as polycrystalline silicon containing an N-type impurity or a P-type impurity.

### Structure of Memory Cell Array Layer LMCA of Chip CM in Hook-Up Region RHU

As shown in FIG. 7, a plurality of contact electrodes CC are provided in the hook-up region RHU. Each of the plurality of contact electrodes CC extends in the Z direction and upper ends of the contact electrodes CC are connected to the conductive layers 110 (i.e., WL, SGD, and SGS).

### Structure of Memory Cell Array Layer LMCA of Chip CM in Peripheral Region RP

For example, as shown in FIG. 6, in the peripheral region RP, the plurality of contact electrodes CC are provided corresponding to the external pad electrodes PX. The upper ends of the plurality of contact electrodes CC are connected to the external pad electrodes PX.

### Structure of Contact Electrode Layer CH of Chip CM

The contact electrode layer CH includes a plurality of contact electrodes. The plurality of contact electrodes may include a stacked film including a barrier conductive film and a metal film, and the like. The barrier conductive film is made of titanium nitride (TiN) or the like. The metal film is made of tungsten (W) or the like.

The plurality of contact electrodes in the contact electrode layer CH are electrically connected to, for example, at least one of the configuration in the memory cell array layer LMCA and the configuration in the chip CP. For example, the contact electrode layer CH includes the plurality of contact electrodes ch. The contact electrodes ch are provided corresponding to the plurality of semiconductor layers 120 and are connected to lower ends of the plurality of semiconductor layers 120.

### Structure of Wiring Layers M0 And M1 of Chip CM

A plurality of wirings in the wiring layers M0 and M1 are electrically connected to, for example, at least one of the configuration in the memory cell array layer LMCA and the configuration in the chip CP.

The wiring layer M0 includes a plurality of wirings m0. The plurality of wirings m0 may include, for example, a stacked film including a barrier conductive film and a metal film, and the like. The barrier conductive film is made of titanium nitride (TiN), tantalum nitride (TaN), a stacked film of tantalum nitride (TaN) and tantalum (Ta), or the like. The metal film is made of copper (Cu) or the like. A part of the plurality of wirings m0 functions as the bit lines BL. For example, as shown in FIG. 8, the bit lines BL are arranged in the X direction and extend in the Y direction.

For example, as shown in FIG. 6, the wiring layer M1 includes a plurality of wirings m1. The plurality of wirings m1 may include, for example, a stacked film including a barrier conductive film and a metal film, and the like. The barrier conductive film is made of titanium nitride (TiN) or the like. The metal film is made of tungsten (W) or the like. For example, as shown in FIGS. 6 and 7, the plurality of wirings m1 are electrically connected to the wiring m0 via contact electrodes V1.

### Structure of Chip Bonding Electrode Layer MB of Chip CM

The plurality of wirings in the chip bonding electrode layer MB are electrically connected to, for example, at least one of the configuration in the memory cell array layer LMCA and the configuration in the chip CP.

The chip bonding electrode layer MB includes a plurality of bonding electrodes PI1 (i.e., bonding pads). The plurality of bonding electrodes PI1 may include, for example, a stacked film including a barrier conductive film pI1B and a metal film pI1M, and the like. The barrier conductive film pI1B is made of titanium nitride (TiN), tantalum nitride (TaN), a stacked film of tantalum nitride (TaN) and tantalum (Ta), or the like. The metal film pI1M is made of copper (Cu) or the like.

### Structure of Chip CP

For example, as shown in FIG. 6, the chip CP includes a semiconductor substrate 200, an electrode layer GC provided above the semiconductor substrate 200, wiring layers D0, D1, D2, D3, and D4 provided above the electrode layer GC, and a chip bonding electrode layer DB provided above the wiring layers D0, D1, D2, D3, and D4.

### Structure of Semiconductor Substrate 200 of Chip CP

The semiconductor substrate 200 includes, for example, P-type silicon (Si) containing a P-type impurity such as boron (B). The surface of the semiconductor substrate 200 is provided with, for example, an N-type well region 200N containing an N-type impurity such as phosphorus (P), a P-type well region 200P containing a P-type impurity such as boron (B), a semiconductor substrate region 200S in which the N-type well region 200N and the P-type well region 200P are not provided, and an insulating region STI. A part of the P-type well region 200P is provided in the semiconductor substrate region 200S, and a part of the P-type well region 200P is provided in the N-type well region 200N. The N-type well region 200N, the P-type well region 200P provided in the N-type well region 200N and the semiconductor substrate region 200S, and the semiconductor substrate region 200S each function as a part of a plurality of transistors Tr and the like configuring the peripheral circuit PC. The insulating region STI includes, for example, silicon oxide (SiO2) and extends in the Z direction.

### Structure of Electrode Layer GC of Chip CP

The electrode layer GC is provided on an upper surface of the semiconductor substrate 200 with an insulating layer 200G interposed therebetween. The electrode layer GC includes a plurality of electrodes gc facing the surface of the semiconductor substrate 200. Each region of the semiconductor substrate 200 and the plurality of electrodes gc in the electrode layer GC are respectively connected to a contact electrode CS.

Each of the plurality of electrodes gc in the electrode layer GC functions as gate electrodes of the transistors Tr configuring the peripheral circuit PC.

The contact electrode CS extends in the Z direction, and a lower end of the contact electrode CS is connected to the semiconductor substrate 200 or an upper surface of the electrode gc. An impurity region containing an N-type impurity or a P-type impurity is provided at a connection portion between the contact electrode CS and the semiconductor substrate 200. The contact electrode CS may include, for example, a stacked film including a barrier conductive film and a metal film, and the like. The barrier conductive film is made of titanium nitride (TiN) or the like. The metal film is made of tungsten (W) or the like.

### Structure of Wiring Layers D0, D1, D2, D3, and D4 of Chip CP

For example, as shown in FIG. 6, a plurality of connection portions and a plurality of wirings in the wiring layers D0, D1, D2, D3, and D4 are electrically connected to, for example, at least one of the configuration in the memory cell array layer LMCA or the configuration in the chip CP.

Each of the wiring layers D0, D1, and D2 includes each of a plurality of wirings d0, d1, and d2 and a plurality of connection portions. The plurality of wirings d0, d1, and d2 and the plurality of connection portions may include, for example, a stacked film including a barrier conductive film and a metal film, and the like. The barrier conductive film is made of titanium nitride (TiN) or the like. The metal film is made of tungsten (W) or the like.

Each of the wiring layers D3 and D4 includes each of a plurality of wirings d3 and d4 and a plurality of connection portions. The plurality of wirings d3 and d4 and the plurality of connection portions may include, for example, a stacked film including a barrier conductive film and a metal film, and the like. The barrier conductive film is made of titanium nitride (TiN), tantalum nitride (TaN), a stacked film of tantalum nitride (TaN) and tantalum (Ta), or the like. The metal film is made of copper (Cu) or the like.

### Structure of Chip Bonding Electrode Layer DB of Chip CP

The plurality of wirings in the chip bonding electrode layer DB are electrically connected to, for example, at least one of the configuration in the memory cell array layer LMCA or the configuration in the chip CP.

The chip bonding electrode layer DB includes a plurality of bonding electrodes PI2. The plurality of bonding electrodes PI2 may include, for example, a stacked film including a barrier conductive film pI2B and a metal film pI2M, and the like. The barrier conductive film pI2B is made of titanium nitride (TiN), tantalum nitride (TaN), a stacked film of tantalum nitride (TaN) and tantalum (Ta), or the like. The metal film pI2M is made of copper (Cu) or the like.

When the metal films pI1M and pI2M made of copper (Cu) or the like are provided in the bonding electrode PI1 and the bonding electrode PI2, the metal films pI1M and pI2M are integrated. Thus, it is not easy to verify the boundary therebetween. However, a bonded structure can be verified by distortion in a bonding shape of the bonding electrode PI1 and the bonding electrode PI2 due to misalignment in bonding and misalignment of the barrier conductive film pI1B and the barrier conductive film pI2B (i.e., discontinuous portions on side surfaces). When the bonding electrode PI1 and the bonding electrode PI2 are formed by a damascene process, each side surface has a tapered shape. Therefore, a sidewall in the cross-sectional shape along the Z direction of a bonded portion of the bonding electrode PI1 and the bonding electrode PI2 is formed in a non-rectangular shape and not a linear shape. When the bonding electrode PI1 and the bonding electrode PI2 are bonded together, each of a lower surface, a side surface, and an upper surface containing Cu provided in the bonding electrode PI1 and the bonding electrode PI2 are covered with barrier metal. In contrast, in a general wiring layer using Cu, an insulating layer having an anti-oxidation function for Cu and made of SiN, SiCN, or the like is provided on the upper surface of the Cu, and barrier metal is not provided thereon. Therefore, even when misalignment in bonding does not occur, the chip bonding electrode layer DB can be distinguished from the general wiring layer.

### Structure of Transistor Tr

As described with reference to FIG. 6 and the like, the chip CP is provided with the plurality of transistors Tr configuring the peripheral circuit PC. The plurality of transistors Tr include high-voltage transistors and low-voltage transistors. The high-voltage transistors include, for example, the word line switch WLSW, the transistors TWLS, TWLU, TDRV1 to TDRV6, and the like described with reference to FIG. 2 and the like. Hereinafter, a configuration of the high-voltage transistors will be described in more detail using the word line switch WLSW as an example.

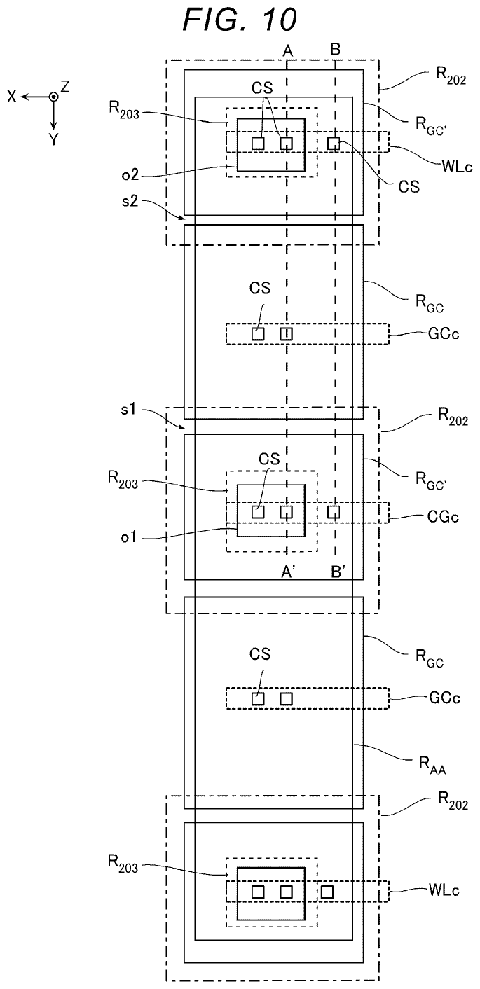

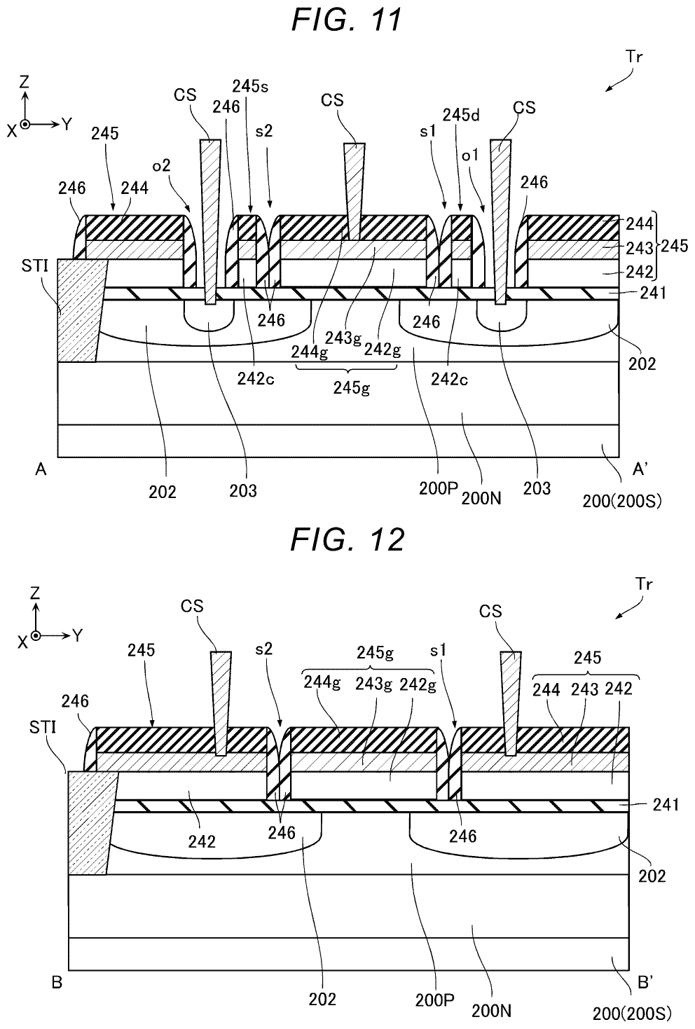

FIG. 10 is a schematic plan view illustrating a structure of the word line switch WLSW according to the first embodiment. FIG. 11 is a schematic cross-sectional view illustrating a structure of the word line switch WLSW cut along a dotted line A-A′ in FIG. 10. FIG. 12 is a schematic cross-sectional view illustrating a structure of the word line switch WLSW cut along a dotted line B-B′ in FIG. 10.

As shown in FIG. 10, an active region RAA surrounded by an insulating region STI is provided in a region of the semiconductor substrate 200 corresponding to the word line switch WLSW. The active region RAA is a region on the surface of the semiconductor substrate 200 other than the insulating region STI (i.e., a region including the N-type well region 200N, the P-type well region 200P, and the semiconductor substrate region 200S described with reference to FIG. 6). Two word line switches WLSW arranged in the Y direction are formed in the active region RAA shown in the drawing.

A gate electrode region RGC and a gate electrode member region RGC′ are provided at a position of the electrode layer GC that overlaps with the active region RAA as viewed from the Z direction. Members used for the gate electrodes (hereinafter also referred to as electrode members) are provided in the gate electrode region RGC and the gate electrode member region RGC′. Slits s1 and s2 without gate electrode members are provided between the gate electrode region RGC and the gate electrode member region RGC′. Openings o1 and o2 are provided inside the gate electrode member region RGC′.

Regions R202 and R203 are provided in the active region RAA. The region R202 is a region containing an N-type impurity, and is a region in which an N− diffusion layer 202 to be described later is provided. The region R203 is a region containing an N-type impurity, and is a region in which an N+ diffusion layer 203 to be described later is provided.

Two wiring regions WLc, a wiring region CGc provided corresponding to the region R202 provided between the two wiring regions WLc, and two wiring regions GCc provided corresponding to the two gate electrode regions RGC are provided at a position on the wiring layer D0 overlapping the active region RAA as viewed from the Z direction. The plurality of contact electrodes CS are provided in the active region RAA.

The wiring d0 in the wiring region WLc functions as a part of a wiring that electrically connects a drain electrode of the word line switch WLSW and the word line WL shown in FIG. 1. Hereinafter, the wiring d0 described here may be referred to as wiring d0 (WL). The contact electrode CS is provided at a position at which the wiring region WLc overlaps with the opening op2 as viewed from the Z direction. An upper end of the contact electrode CS is connected to the wiring d0 (WL). A lower end of the contact electrode CS is connected to the N+ diffusion layer 203 to be described later with reference to FIG. 11. The contact electrode CS functions as a drain electrode of the word line switch WLSW. Another contact electrode CS is provided at a position at which the wiring region WLc and the gate electrode member region RGC′ overlap as viewed from the Z direction. An upper end of the contact electrode CS is connected to the wiring d0 (WL). A lower end of the contact electrode CS is connected to a gate electrode member portion 245 to be described later with reference to FIG. 12.

The wiring d0 in the wiring region CGc functions as a part of a wiring that electrically connects a source electrode of the word line switch WLSW and the wiring CGI shown in FIGS. 2 and 3. Hereinafter, the wiring d0 described here may be referred to as the wiring d0 (CGI). The contact electrode CS is provided at a position at which the wiring region CGc overlaps with the opening op1 as viewed from the Z direction. An upper end of the contact electrode CS is connected to the wiring d0 (CGI). A lower end of the contact electrode CS is connected to the N+ diffusion layer 203 to be described later with reference to FIG. 11. The contact electrode CS functions as a source electrode of the word line switch WLSW. Another contact electrode CS is provided at a position at which the wiring region CGc overlaps with the gate electrode member region RGC′ as viewed from the Z direction. An upper end of the contact electrode CS is connected to the wiring d0 (CGI). A lower end of the contact electrode CS is connected to the gate electrode member portion 245 to be described later with reference to FIG. 12.

The wiring d0 in the wiring region GCc functions as the signal supply line BLKSEL shown in FIGS. 2 and 3. Hereinafter, the wiring d0 described here may be referred to as the wiring d0 (BLKSEL). The contact electrode CS is provided at a position at which the wiring region GCc overlaps with the gate electrode region RGC as viewed from the Z direction. An upper end of the contact electrode CS is connected to the wiring d0 (BLKSEL). A lower end of the contact electrode CS is connected to a gate electrode 245g to be described later with reference to FIG. 11.

For example, as shown in FIGS. 11 and 12, the semiconductor substrate region 200S of the semiconductor substrate 200 has a double well structure. For example, in the double well structure, the N-type well region 200N is provided on the surface of the P-type semiconductor substrate 200, and the P-type well region 200P is provided in the N-type well region 200N. The insulating region STI made of silicon oxide (SiO2) or the like is provided in the semiconductor substrate region 200S. The P-type well region 200P described here is an example of the P-type well region 200P described with reference to FIG. 6. The N-type well region 200N described here is an example of the N-type well region 200N described with reference to FIG. 6. The N-type well region 200N and the P-type well region 200P may not be provided in the semiconductor substrate region 200S.

For example, as shown in FIG. 11, the word line switch WLSW is provided in the P-type well region 200P of the semiconductor substrate 200.

The word line switch WLSW includes a part of the P-type well region 200P, a gate insulating film 241, the gate electrode 245g, the gate electrode member portion 245, and a sidewall insulating film 246. The gate insulating film 241 is provided on the surface of the semiconductor substrate 200 and is made of silicon oxide (SiO2) or the like. The gate electrode 245g is provided on an upper surface of the gate insulating film 241. The sidewall insulating film 246 is provided on side surfaces of the gate electrode 245g and the gate electrode member portion 245 in the X direction or the Y direction.

The gate electrode 245g is an electrode member provided in the gate electrode region RGC shown in FIG. 10. The gate electrode 245g is provided between the contact electrode CS functioning as a source electrode and the contact electrode CS functioning as a drain electrode. The gate electrode 245g faces the semiconductor substrate 200 with the gate insulating film 241 interposed therebetween.

More specifically, as shown in FIG. 11, the gate electrode 245g includes a gate electrode member 242g, a gate electrode member 243g, and a cap insulating layer 244g. The gate electrode member 242g is provided on the upper surface of the gate insulating film 241 and is made of polycrystalline silicon (Si) or the like. The gate electrode member 243g is provided on an upper surface of the gate electrode member 242g and is made of tungsten (W) or the like. The cap insulating layer 244g is provided on an upper surface of the gate electrode member 243g and is made of silicon nitride (Si3N4) or the like. The gate electrode 245g further includes the sidewall insulating film 246 provided on the side surfaces of the gate electrode member 242g, the gate electrode member 243g, and the cap insulating layer 244g in the X direction or the Y direction and made of silicon oxide (SiO2), silicon nitride (Si3N4), or the like. The gate electrode member 242g is an N+ layer containing an N-type impurity such as phosphorus (P). An impurity concentration of the N-type impurity contained in the gate electrode member 242g is higher than an impurity concentration of the N-type or P-type impurity contained in a gate electrode member 242c to be described later. Each of the gate electrode member 242g and the gate electrode member 243g is one of the plurality of electrodes gc described with reference to FIG. 6 and the like, and functions as the gate electrode 245g provided on the gate insulating film 241. The gate insulating film 241 is one of the plurality of insulating layers 200G described with reference to FIG. 6 and the like.

Gate electrode member portions 245s and 245d are electrode members provided in the gate electrode member region RGC′ shown in FIG. 10. The gate electrode member portion 245s is located in the gate electrode member region RGC′ between the opening o2 and the slit s2. The gate electrode member portion 245d is located in the gate electrode member region RGC′ between the opening o1 and the slit s1. For example, as shown in FIG. 11, the gate electrode member portions 245s and 245d face a region between a contact portion coming into contact with the contact electrode CS and a facing portion facing the gate electrode 245g.

More specifically, the gate electrode member portions 245s and 245d have the same configuration as the gate electrode 245g. That is, as shown in FIG. 11, the gate electrode member portions 245s and 245d each include the gate electrode member 242c, a gate electrode member 243, and a cap insulating layer 244. The gate electrode member 242c is provided on the upper surface of the gate insulating film 241 and is made of polycrystalline silicon (Si) or the like. The gate electrode member 243 is provided on an upper surface of the gate electrode member 242c and is made of tungsten (W) or the like. The cap insulating layer 244 is provided on an upper surface of the gate electrode member 243 and is made of silicon nitride (Si3N4) or the like. The gate electrode member portions 245s and 245d further include the sidewall insulating film 246 provided on side surfaces of the gate electrode member 242c, the gate electrode member 243, and the cap insulating layer 244 in the X direction or the Y direction. The gate electrode member 242c is, for example, an N− layer containing an N-type impurity such as phosphorus (P) or a P− layer containing a P-type impurity such as boron (B). An impurity concentration of the N-type or P-type impurity contained in the gate electrode member 242c is lower than an impurity concentration of the N-type impurity contained in the gate electrode member 242g.

The gate electrode member portion 245 is an electrode member provided in the gate electrode member region RGC′ shown in FIG. 10. The gate electrode member portion 245 is located in the gate electrode member region RGC′ except for a region between the opening o1 and the slit s1 and a region between the opening o2 and the slit s2.

More specifically, as shown in FIG. 11, the gate electrode member portion 245 includes a gate electrode member 242, the gate electrode member 243, and the cap insulating layer 244. The gate electrode member 242 is provided on the upper surface of the gate insulating film 241 and is made of polycrystalline silicon (Si) or the like. The gate electrode member 243 is provided on an upper surface of the gate electrode member 242. The cap insulating layer 244 is provided on the upper surface of the gate electrode member 243. The gate electrode member portion 245 further includes the sidewall insulating film 246 provided on side surfaces of the gate electrode member 242, the gate electrode member 243, and the cap insulating layer 244 in the X direction or the Y direction. The gate electrode member 242 contains, for example, an N-type impurity such as phosphorus (P) or a P-type impurity such as boron (B). An impurity concentration of the N-type or P-type impurity contained in the gate electrode member 242 is equal to or lower than an impurity concentration of the N-type impurity contained in the gate electrode member 242g. In other words, the gate electrode member 242 may be an N− layer or a P− layer, or may be an N+ layer or a P+ layer.

For example, as shown in FIG. 11, the contact electrode CS extending in the Z direction is connected to the word line switch WLSW. The contact electrode CS may include, for example, a stacked film including a barrier conductive film and a metal film, and the like. The barrier conductive film is made of titanium nitride (TiN) or the like. The metal film is made of tungsten (W) or the like. A part of the contact electrodes CS penetrates the gate insulating film 241 and are connected to the N+ diffusion layer 203 on the surface of the semiconductor substrate 200, thereby functioning as source electrodes or drain electrodes of the word line switch WLSW. A part of the contact electrodes CS penetrates the cap insulating layer 244g and are connected to the upper surface of the gate electrode member 243.

The word line switch WLSW includes a channel region not shown in the drawing on the surface of the semiconductor substrate 200 facing the gate electrode member 242. For example, as shown in FIG. 11, the N− diffusion layer 202 and the N+ diffusion layer 203 are provided on the surface of the semiconductor substrate 200. For example, in FIG. 11, the N− diffusion layer 202 and the N+ diffusion layer 203 on a negative side in the Y direction function as source regions. The N− diffusion layer 202 and the N+ diffusion layer 203 on a positive side in the Y direction function as drain regions.

The N+ diffusion layer 203 is a diffusion layer region provided in the semiconductor substrate 200, connected to the contact electrode CS extending in the Z direction, and containing a first conductivity type impurity. The N+ diffusion layer 203 is provided at a position overlapping with the region R203 shown in FIG. 10 as viewed from the Z direction. The first conductivity type impurity is, for example, an N-type impurity such as phosphorus (P) or arsenic (As). An impurity concentration of the N-type impurity contained in the N+ diffusion layer 203 is higher than an impurity concentration of the N-type impurity contained in the N− diffusion layer 202.

The N− diffusion layer 202 is a diffusion layer region provided in the semiconductor substrate 200 and containing an impurity of the first conductivity type. The N− diffusion layer 202 is provided at a position overlapping with the region R202 shown in FIG. 10 as viewed from the Z direction. An impurity concentration of the N-type impurity contained in the N− diffusion layer 202 is lower than an impurity concentration of the N-type impurity contained in the N+ diffusion layer 203.

Impurity may be introduced into the channel region of the word line switch WLSW. For example, when a threshold voltage is desired to be set to a positive value, a P-type impurity such as boron (B) may be introduced into the channel region. Here, the threshold voltage is a gate-to-source voltage by which the word line switch WLSW transitions from an off state to an on state. Meanwhile, when the threshold voltage is desired to be set to a negative value, an N-type impurity such as arsenic may be introduced into the channel region.

### Method of Manufacturing Transistor Tr

Next, a method of manufacturing a high-voltage transistor among the transistors Tr according to the first embodiment will be described with reference to FIGS. 13 to 24. FIGS. 13 to 24 are schematic cross-sectional views illustrating the method of manufacturing the high-voltage transistor, and show cross sections corresponding to FIG. 11.

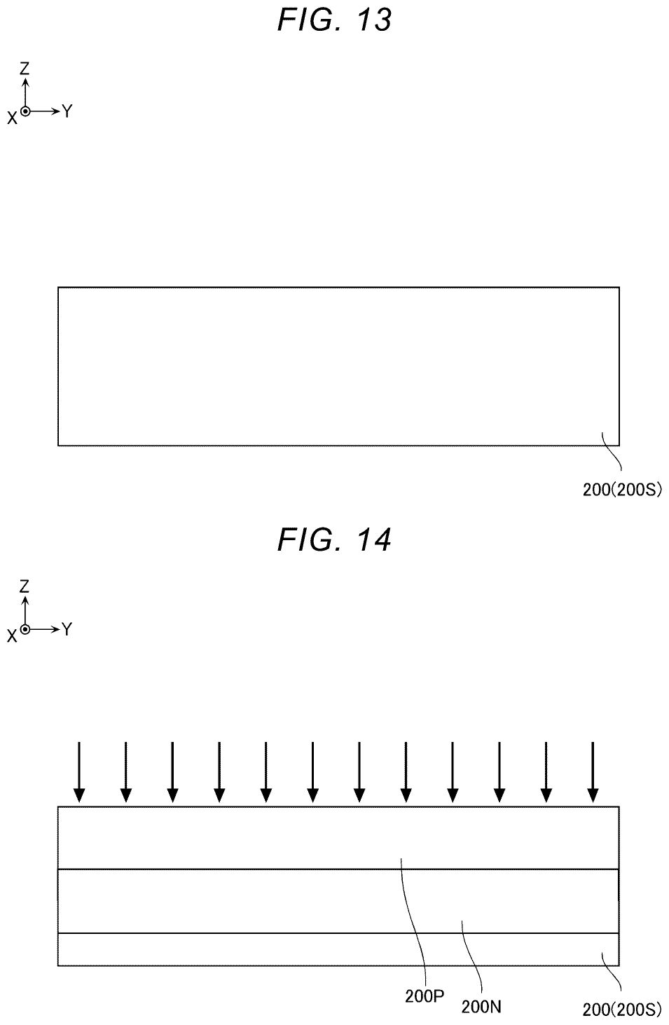

First, as shown in FIG. 13, the semiconductor substrate 200 (i.e., the semiconductor substrate region 200S) is provided. As shown in FIG. 14, an N-type impurity such as phosphorus (P) is implanted to the surface of the semiconductor substrate 200 (i.e., the semiconductor substrate region 200S) and the N-type well region 200N is formed. A P-type impurity such as boron (B) is implanted to the semiconductor substrate 200 and the P-type well region 200P is formed. The process is performed by, for example, ion implantation. Specifically, a resist provided with an opening in a region corresponding to the N-type well region 200N is formed on the surface of the semiconductor substrate 200. Then, an N-type impurity such as phosphorus (P) is introduced to the semiconductor substrate 200 by, for example, ion implantation. The resist provided with the opening in the region corresponding to the N-type well region 200N is peeled off. A resist provided with an opening in a region corresponding to the P-type well region 200P is formed. A P-type impurity such as boron (B) is introduced to the semiconductor substrate 200 by, for example, ion implantation. As such, the N-type well region 200N and the P-type well region 200P are formed in the semiconductor substrate 200.

Next, for example, as shown in FIG. 15, an N-type impurity such as phosphorus (P) is implanted to a surface of the P-type well region 200P and the N− diffusion layer 202 is formed. The process is performed by, for example, ion implantation. Specifically, a resist 351 provided with an opening in a region corresponding to the N− diffusion layer 202 is formed on the surface of the P-type well region 200P. An N-type impurity such as phosphorus (P) is introduced to the P-type well region 200P by, for example, ion implantation and the N− diffusion layer 202 is formed.

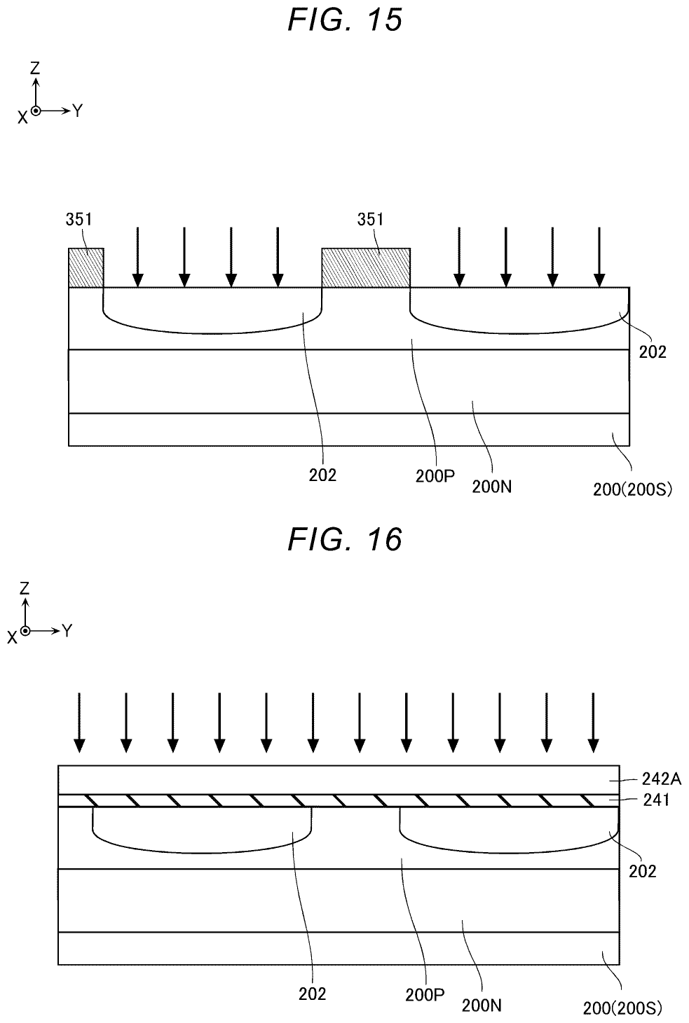

Next, for example, as shown in FIG. 16, the gate insulating film 241 such as silicon oxide is formed on the upper surface of the semiconductor substrate 200. The process is performed by, for example, thermal oxidation. Next, a semiconductor layer of polycrystalline silicon (Si) is formed, an N-type impurity such as phosphorus (P) is implanted to the formed semiconductor layer by ion implantation, and an N− layer gate electrode member 242A is formed. The process of forming the semiconductor layer is performed by, for example, CVD.

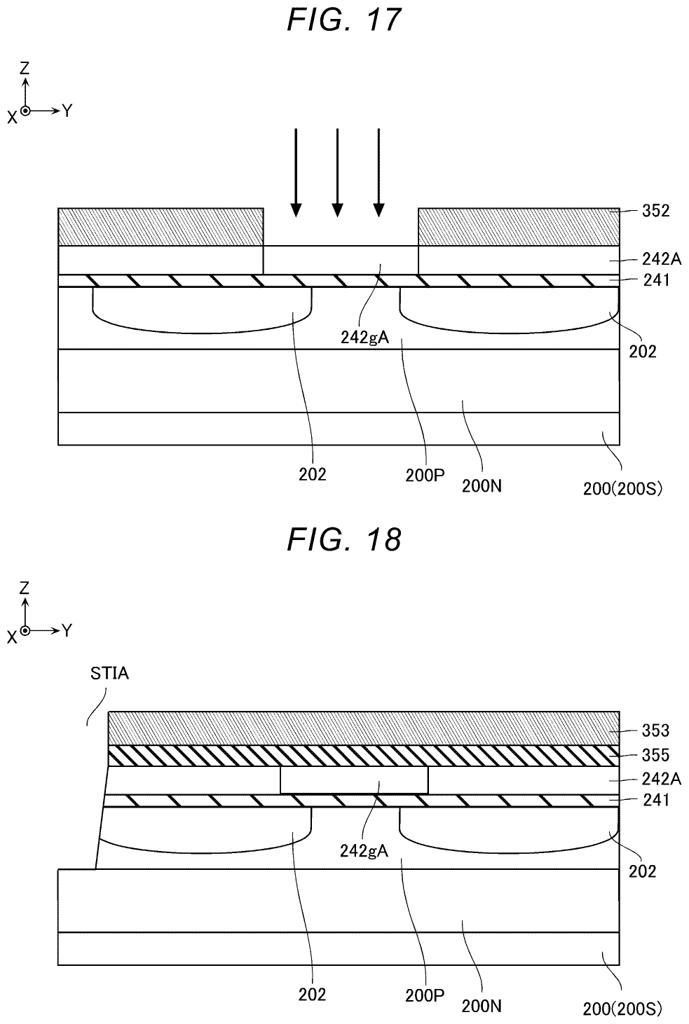

Next, for example, as shown in FIG. 17, a resist 352 provided with an opening in a region corresponding to the gate electrode member 242g is formed on a surface of the gate electrode member 242A. An N-type impurity such as phosphorus (P) is introduced to the resist 352 and an N+ layer gate electrode member 242gA is formed. The process is performed by, for example, ion implantation.

Next, for example, as shown in FIG. 18, a mask material 355 such as SiN is formed on surfaces of the gate electrode member 242A and the gate electrode member 242gA. Next, a resist 353 provided with an opening in a region corresponding to the insulating region STI shown in FIG. 11 is formed. The mask material 355, the gate electrode member 242A, the gate insulating film 241, and the semiconductor substrate 200 at a position corresponding to the insulating region STI are removed and an opening STIA is formed. The opening STIA extends in the Z direction and the X or Y direction, penetrates the gate electrode member 242A and the gate insulating film 241, and divides a part of the surface of the semiconductor substrate 200. The process is performed by a method such as reactive ion etching (RIE).

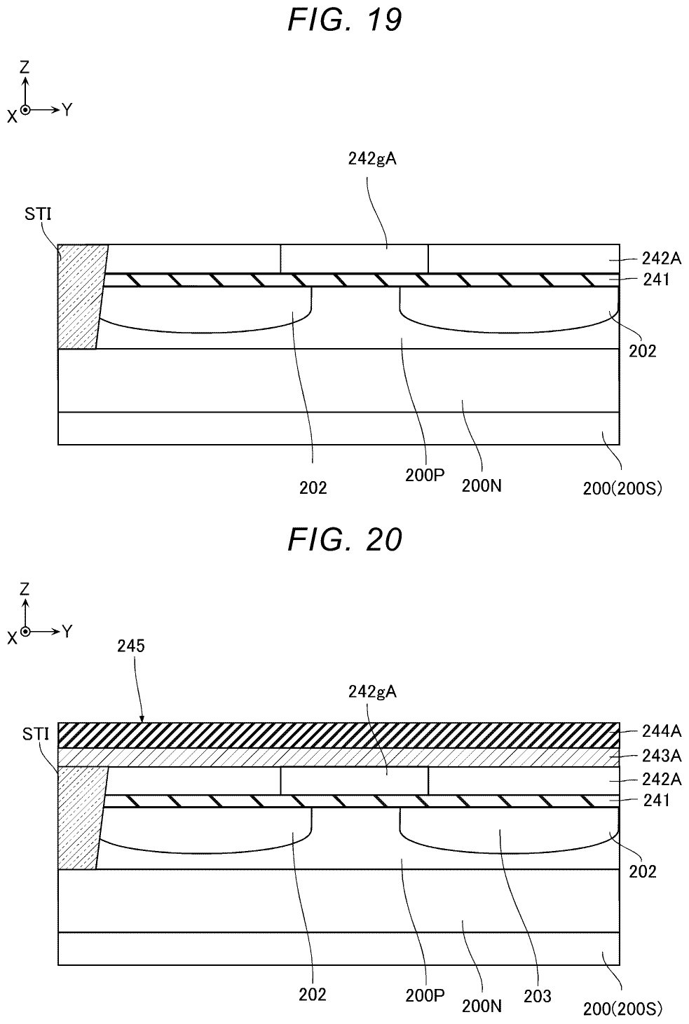

Next, for example, as shown in FIG. 19, an insulating layer is embedded in the opening STIA, the mask material 355 and a part of the formed insulating layer are removed, and the insulating region STI is formed. The process of embedding the insulating layer is performed by, for example, CVD. The process of removing the mask material 355 is performed by, for example, RIE. The process of removing a part of the formed insulating layer is performed by, for example, chemical mechanical polishing (CMP).

Next, for example, as shown in FIG. 20, a gate electrode member 243A made of tungsten (W) or the like and a cap insulating layer 244A made of silicon oxide (SiO2), silicon nitride (Si3N4), or the like are stacked in this order on upper surfaces of the gate electrode member 242A, the gate electrode member 242gA, and the insulating region STI. The process is performed by, for example, CVD.

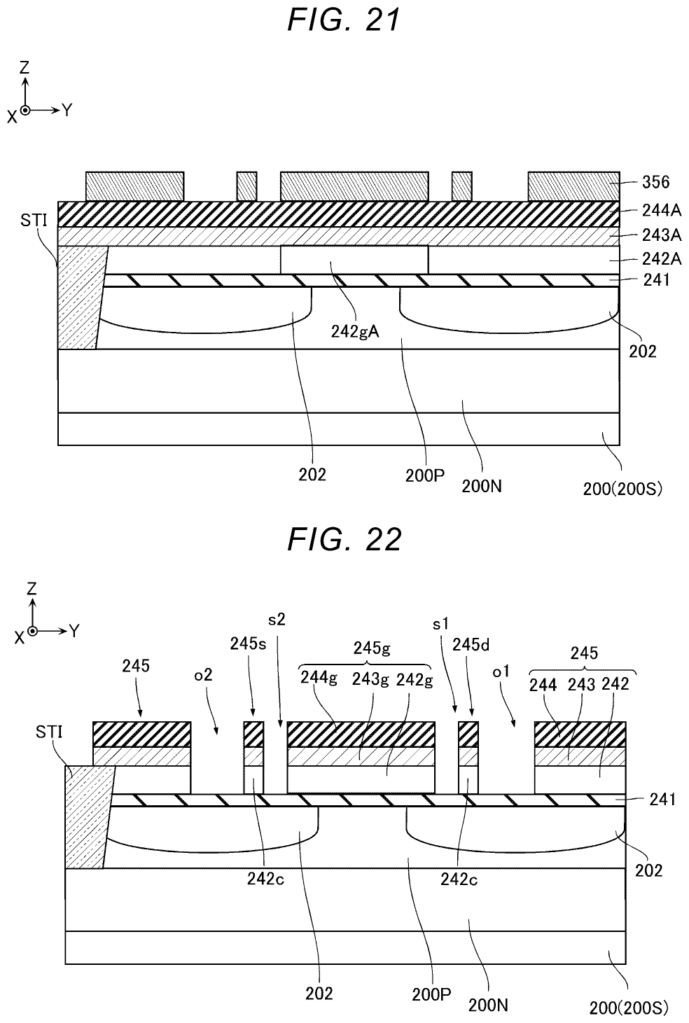

Next, for example, as shown in FIG. 21, a resist 356 provided with openings in regions other than the regions corresponding to the gate electrode 245g and the gate electrode member portions 245, 245s, and 245d is formed.

Next, for example, as shown in FIG. 22, the gate electrode member 242A, the gate electrode member 242gA, the gate electrode member 243A, and the cap insulating layer 244A are removed from positions except for regions to be the gate electrode 245g and the gate electrode member portions 245, 245s, and 245d (that is, positions of the openings o1, o2 and the slits s1, s2). The step is performed by, for example, a method such as RIE. As such, the gate electrode 245g and the gate electrode member portions 245, 245s, and 245d of the transistor Tr are formed.

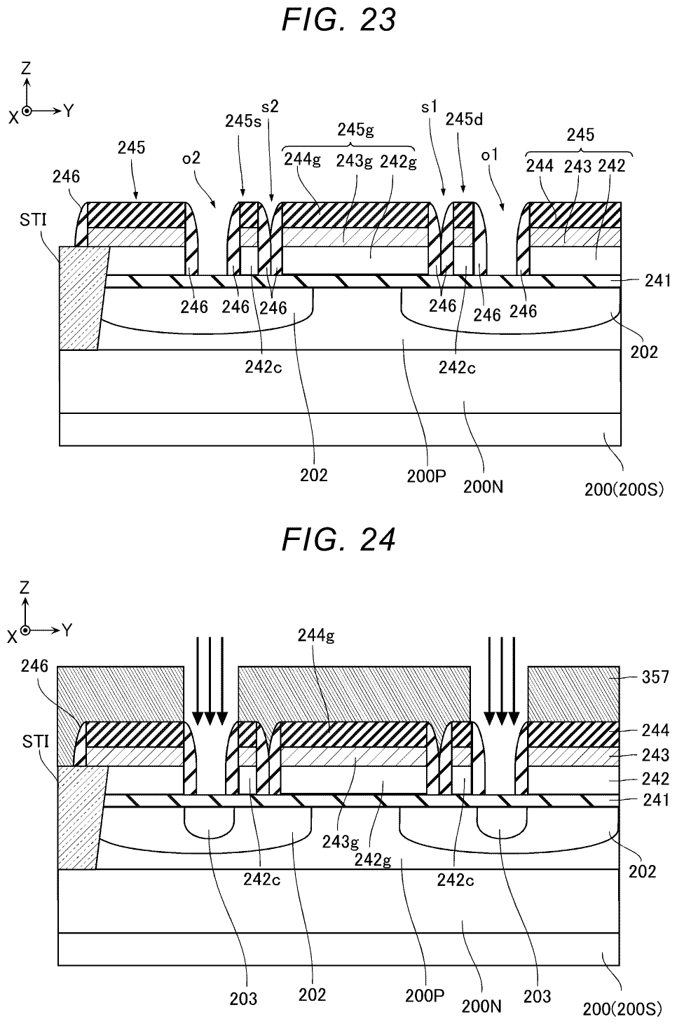

Next, for example, as shown in FIG. 23, silicon oxide (SiO2) or silicon nitride (Si3N4) is deposited on side surfaces in the X direction and the Y direction and on upper surfaces of the gate electrode 245g and the gate electrode member portions 245, 245s, and 245d. A part of the deposited silicon oxide (SiO2) or silicon nitride (Si3N4) formed on the upper surfaces of the gate electrode 245g and the gate electrode member portion 245 is removed by anisotropic etching. Thereby, the sidewall insulating film 246 is formed.

Next, for example, as shown in FIG. 24, a resist 357 provided with openings in regions corresponding to the openings o1 and o2 is formed, an N-type impurity such as phosphorus (P) or arsenic (As) is ion-implanted, and the N+ diffusion layer 203 is formed.

Thereafter, the contact electrode CS described with reference to FIG. 11 is formed by a method such as CVD and a high-voltage transistor as described with reference to FIG. 10 to FIG. 12 is formed.

For example, when the resist 352 is formed as described with reference to FIG. 17, the resist 352 provided with openings in the regions corresponding to the gate electrode member 242 and the gate electrode member 242g may be formed. Then, for example, an N-type impurity such as phosphorus (P) may be introduced to the resist 352 to form the gate electrode member 242A and the N+ layer gate electrode member 242gA, in which the gate electrode member 242A includes a region to be the N+ layer gate electrode member 242 and a region to be the N− layer gate electrode member 242c. Thereby, a transistor Tr including the N+ layer gate electrode member 242 and the N− layer gate electrode member 242c can be formed.

When forming the transistor Tr including the N+ layer gate electrode member 242 and the N− layer gate electrode member 242c, for example, the resist 352 described with reference to FIG. 17 may not be formed, and instead, an N+ layer gate electrode member 242A and the N+ layer gate electrode member 242gA may be formed by introducing an N-type impurity such as phosphorus (P). Here, after the N+ layer gate electrode member 242A and the N+ layer gate electrode member 242gA are formed, a resist provided with openings in regions corresponding to the gate electrode member portions 245s and 245d may be formed, a P-type impurity (i.e., counter dope) such as boron (B) may be ion-implanted to the resist, and the N− layer gate electrode member 242c may be formed.

### COMPARATIVE EXAMPLES

### Configuration

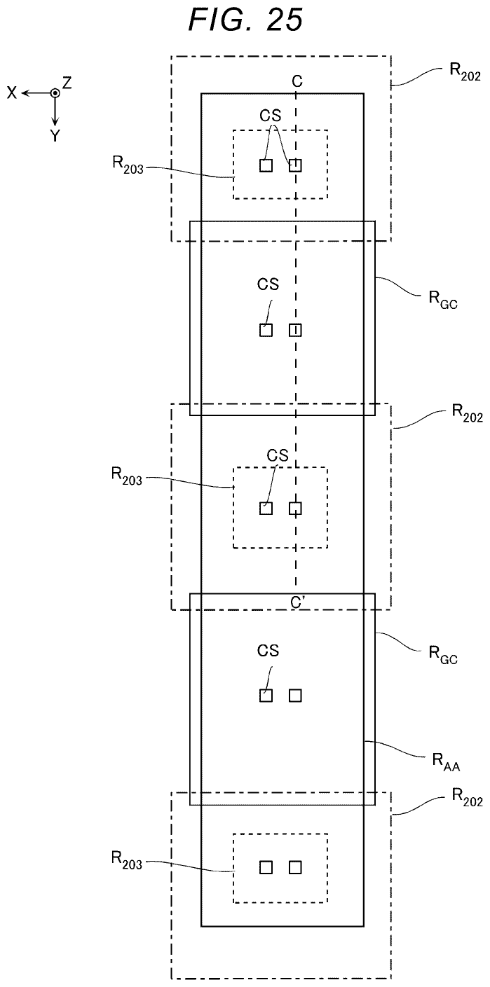

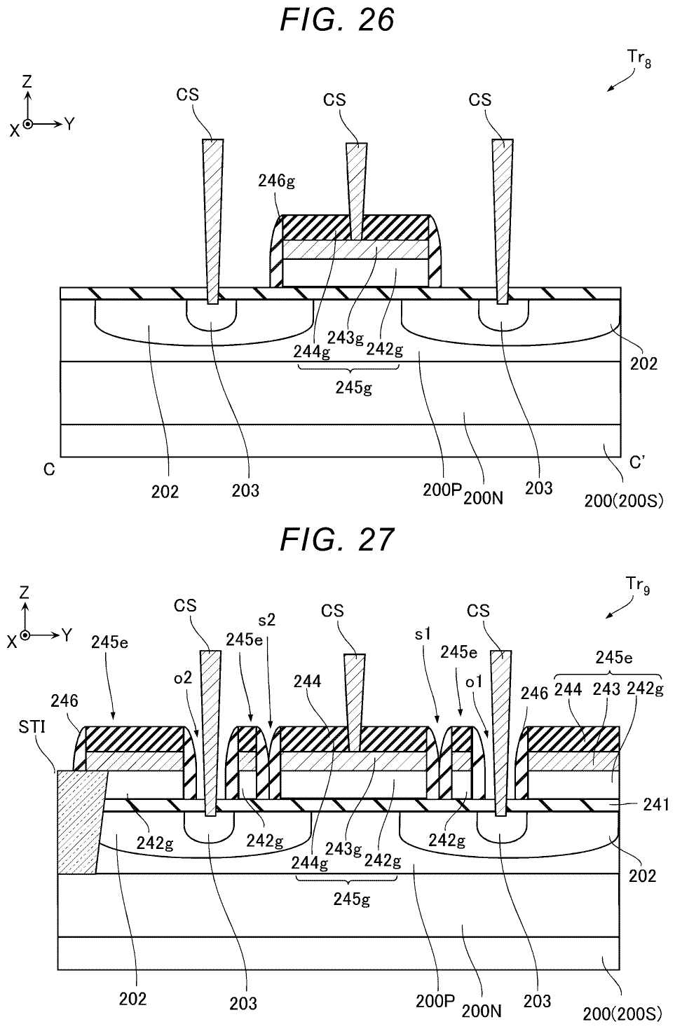

Next, a structure of a transistor Tr8 according to a first comparative example will be described with reference to FIGS. 25 and 26. FIG. 25 is a schematic plan view illustrating the structure of the transistor Tr8 according to the first comparative example. FIG. 26 is a schematic cross-sectional view illustrating the structure of the transistor Tr8 cut along a dotted line CC′ in FIG. 25.

The transistor Tr8 according to the first comparative example is provided with the gate electrode region RGC as shown in FIG. 25. However, the transistor Tr8 according to the first comparative example is not provided with the gate electrode member region RGC′. In other words, the transistor Tr8 according to the first comparative example is provided with the gate electrode 245g, but is not provided with the gate electrode member portions 245, 245s, and 245d, as shown in FIG. 26.

Next, a structure of a transistor Tr9 according to a second comparative example will be described with reference to FIG. 27. FIG. 27 is a schematic plan view illustrating the structure of the transistor Tr9 according to the second comparative example.

The transistor Tr9 according to the second comparative example is provided with a gate electrode member portion 245e instead of the gate electrode member portions 245, 245s, and 245d, as shown in FIG. 27. The gate electrode member portion 245e includes the gate electrode member 242g, the gate electrode member 243, and the cap insulating layer 244. That is, in the transistor Tr9 according to the second comparative example, an impurity concentration of the N-type impurity contained in the gate electrode member 242g of the gate electrode 245g is equal to an impurity concentration of the N-type impurity contained in the gate electrode member 242g of the gate electrode member portion 245e.

### Effects of First Embodiment

In the transistor Tr8 according to the first comparative example described with reference to FIGS. 25 and 26, the gate electrode member region RGC′ (i.e., gate electrode member portions 245, 245s, and 245d) is not provided. Therefore, an electric field generated from a wiring provided above reaches a region (i.e., N+ diffusion layer 203) between the contact electrode CS functioning as the source electrode or the drain electrode of the transistor Tr and the gate electrode 245g on the upper surface of the semiconductor substrate 200. As a result, there is a concern that the electric field affects transistor characteristics.

In contrast, as shown in FIG. 11 and the like, in the transistor Tr according to the first embodiment, the gate electrode member portion 245 covers the above-mentioned region on the upper surface of the semiconductor substrate 200. Thereby, in the transistor Tr according to the first embodiment, by shielding the above-mentioned region on the upper surface of the semiconductor substrate 200 from the electric field generated from the wiring provided above, the electric field can be prevented from reaching the above-mentioned region and can be prevented from affecting the transistor characteristics.

In the transistor Tr9 according to the second comparative example described with reference to FIG. 27, the gate electrode member portion 245e covers the above-mentioned region on the upper surface of the semiconductor substrate 200. Therefore, the effect on the transistor characteristics can be reduced in the second comparative example as well. However, in the transistor Tr9 according to the second comparative example, both the gate electrode member 242g of the gate electrode 245g and the gate electrode member 242g of the gate electrode member portion 245e are N+ layers. Therefore, when a large voltage difference occurs between the gate electrode and the source electrode or the drain electrode, an electric field is concentrated at a position on the upper surface of the semiconductor substrate 200 that overlaps with the slits s1 and s2 as viewed from the Z direction. As a result, insulation breakdown may occur.

In contrast, in the transistor Tr according to the first embodiment, the gate electrode member portions 245d and 245s provided with the gate electrode members 242c are provided in the above-mentioned region on the upper surface of the semiconductor substrate 200. The gate electrode member 242c is an N− layer with an impurity concentration lower than an impurity concentration of the N-type impurity contained in the N+ layer gate electrode member 242g. Therefore, when a large voltage difference occurs between the gate electrode and the source electrode or the drain electrode, a potential gradient is easily formed in the gate electrode member 242c. Thereby, it is possible to weaken the concentration of the electric field at the position on the upper surface of the semiconductor substrate 200 that overlaps with the slits s1 and s2 as viewed from the Z direction and occurrence of insulation breakdown can be prevented. As a result, a transistor Tr having high breakdown voltage can be provided.

### Modification Example of First Embodiment

In the first embodiment described above, a gate electrode member made of tungsten (W) or the like is used for a gate electrode and a gate electrode member portion of a high-voltage transistor. However, configurations of the gate electrode and gate electrode member portion of the high-voltage transistor is not limited thereto. For example, a gate electrode member made of silicide or the like may be used for the gate electrode and the gate electrode member portion. Hereinafter, as a modification example of the first embodiment, a transistor Tr1 using a gate electrode member made of silicide or the like for a gate electrode and a gate electrode member portion will be described. The transistor Tr1 is a high-voltage transistor used as the word line switch WLSW.

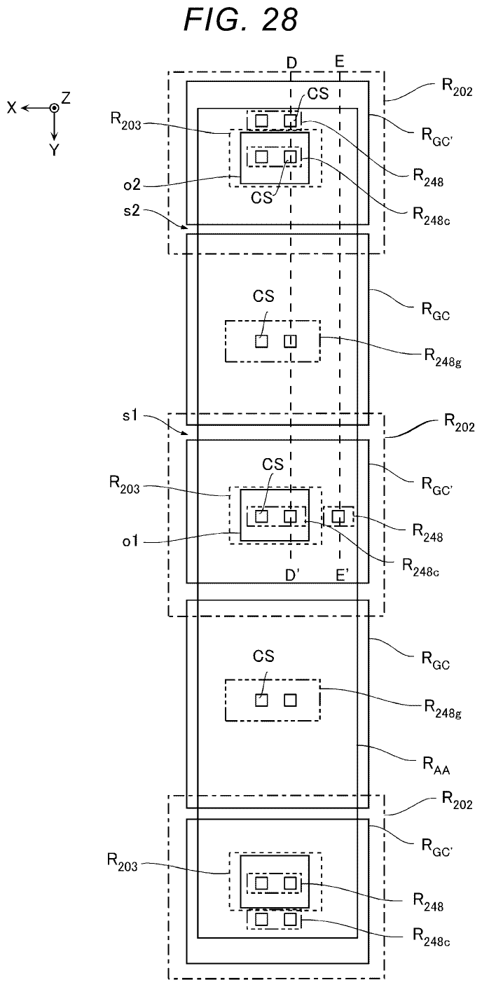

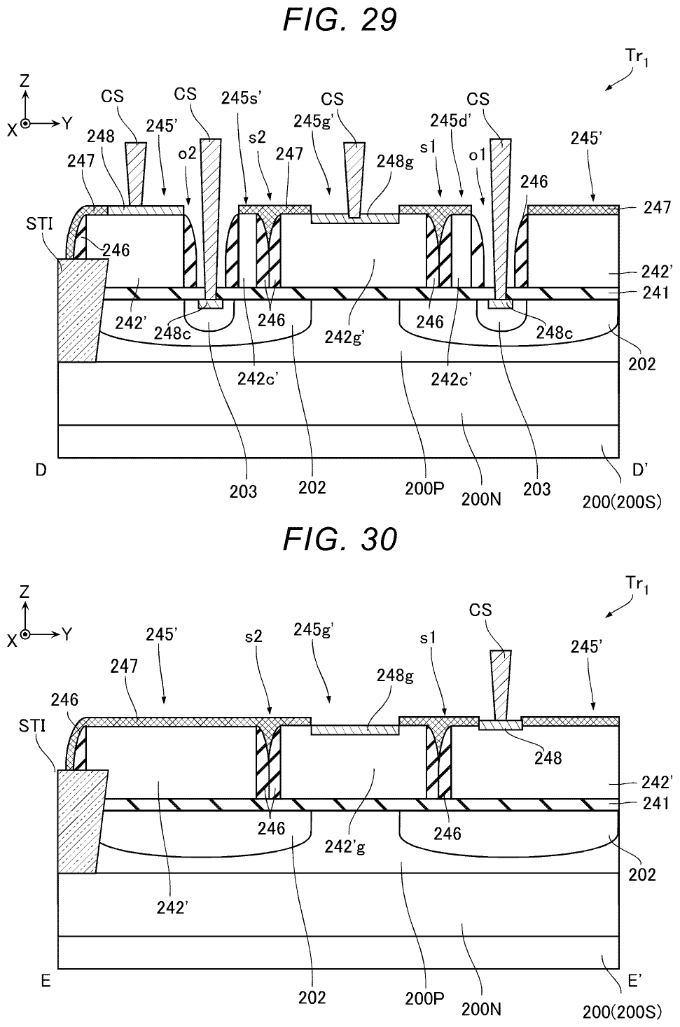

FIG. 28 is a schematic plan view illustrating a structure of the transistor Tr1 according to the modification example of the first embodiment. FIG. 29 is a schematic cross-sectional view illustrating the structure of the transistor Tr1 cut along a dotted line D-D′ in FIG. 28. FIG. 30 is a schematic cross-sectional view illustrating the structure of the transistor Tr1 cut along a dotted line E-E′ in FIG. 28. The same components as in FIGS. 10 to 12 are represented by the same reference numerals and signs, and the description thereof will not be repeated.

As shown in FIG. 28 and the like, the transistor Tr1 according to the modification example of the first embodiment includes the contact electrodes CS connected to a part of the gate electrode members 242, and positions of the contact electrodes CS are different compared to the word line switch WLSW according to the first embodiment shown in FIG. 10 and other drawings, and silicide is formed in the region including the contact portion coming into contact with the contact electrode CS. As shown in FIG. 29, the transistor Tr1 according to the modification example of the first embodiment includes a gate electrode 245g′ and gate electrode member portions 245′, 245s′, and 245d′ instead of the gate electrode 245g and the gate electrode member portions 245, 245s, and 245d.

The gate electrode 245g′ is an electrode member provided in the gate electrode region RGC shown in FIG. 28. The gate electrode 245g′ is provided between the contact electrode CS functioning as a source electrode and the contact electrode CS functioning as a drain electrode, and faces the semiconductor substrate 200 with the gate insulating film 241 interposed therebetween.

More specifically, as shown in FIG. 29, the gate electrode 245g′ includes a gate electrode member 242g′ and a silicide portion 248g. The gate electrode member 242g′ is provided on the upper surface of the gate insulating film 241 and is made of polycrystalline silicon (Si) or the like. The silicide portion 248g is provided on an upper surface of the gate electrode member 242g′. The gate electrode 245g′ further includes the sidewall insulating film 246 provided on a side surface of the gate electrode member 242g′ in the X direction or the Y direction. The gate electrode member 242g′ is, for example, an N+ layer containing an N-type impurity such as phosphorus (P). An impurity concentration of the N-type impurity contained in the gate electrode member 242g′ is higher than an impurity concentration of the N-type or P-type impurity contained in a gate electrode member 242c′ to be described later. The silicide portion 248g may be, for example, a region formed by forming silicide on a part of the upper surface of the gate electrode member 242g′. The silicide portion 248g includes a contact portion coming into contact with the contact electrode CS.

A block insulating film 247 for preventing silicide formation and made of silicon oxide (SiO2), silicon nitride (Si3N4), or the like is provided on a region of the upper surface of the gate electrode 245g′ (i.e., the gate electrode member 242g′) other than the silicide portion 248g and on upper surfaces of the gate electrode member portions 245s′ and 245d′ (i.e., the gate electrode member 242c′) to be described later.

The gate electrode member portions 245s′ and 245d′ are electrode members provided in the gate electrode member region RGC′ shown in FIG. 28. The gate electrode member portion 245s′ is located in the gate electrode member region RGC′ between the opening o2 and the slit s2. The gate electrode member portion 245d′ is located in the gate electrode member region RGC′ between the opening o1 and the slit s1. For example, as shown in FIG. 29, the gate electrode member portions 245s′ and 245d′ face a region between the contact portion coming into contact with the contact electrode CS and a facing portion facing the gate electrode 245g′.

More specifically, the gate electrode member portions 245s′ and 245d′ include the gate electrode member 242c′ provided on the upper surface of the gate insulating film 241 and made of polycrystalline silicon (Si) or the like, as shown in FIG. 29. The gate electrode member portions 245s′ and 245d′ further include the sidewall insulating film 246 provided on a side surface of the gate electrode member 242c′ in the X direction or the Y direction. The gate electrode member 242c′ is, for example, an N− layer containing an N-type impurity such as phosphorus (P) or a P− layer containing a P-type impurity such as boron (B). An impurity concentration of the N-type or P-type impurity contained in the gate electrode member 242c′ is lower than an impurity concentration of the N-type impurity contained in the gate electrode member 242g′.

The gate electrode member portion 245′ is an electrode member provided in the gate electrode member region RGC′ shown in FIG. 28. The gate electrode member portion 245′ is located in the gate electrode member region RGC′ except for a region between the opening o1 and the slit s1 and a region between the opening o2 and the slit s2.

More specifically, the gate electrode member portion 245′ includes a gate electrode member 242′ provided on the upper surface of the gate insulating film 241 and made of polycrystalline silicon (Si) or the like, as shown in FIG. 29. The block insulating film 247 made of silicon oxide (SiO2), silicon nitride (Si3N4), or the like is provided on an upper surface of the gate electrode member portion 245′ (i.e., the gate electrode member 242′). The gate electrode member portion 245′ on the opening o2 side includes a silicide portion 248 provided on an upper surface of the gate electrode member 242′. The silicide portion 248 is not provided with the block insulating film 247. The gate electrode member 242′ contains, for example, an N-type impurity such as phosphorus (P) or a P-type impurity such as boron (B). An impurity concentration of the N-type or P-type impurity contained in the gate electrode member 242′ is equal to or lower than an impurity concentration of the N-type impurity contained in the gate electrode member 242g′. In other words, the gate electrode member 242′ may be an N− layer or a P− layer, or may be an N+ layer or a P+ layer. The silicide portion 248 may be, for example, a region formed by forming silicide on a part of the upper surface of the gate electrode member 242′. The silicide portion 248 includes a contact portion coming into contact with the contact electrode CS.

In the present embodiment, a silicide portion 248c is provided in the N+ diffusion layer 203. The silicide portion 248c may be a region formed by forming silicide on a part of the upper surface of the N+ diffusion layer 203. The silicide portion 248c includes a contact portion coming into contact with the contact electrode CS.

### Effects of Modification Example of First Embodiment

The transistor Tr1 according to the modification example of the first embodiment is able to achieve the same effects as the high-voltage transistor according to the first embodiment. In the transistor Tr1 according to the modification example of the first embodiment, compared to the transistor Tr according to the first embodiment, the contact electrode CS connected to a part of the gate electrode member portion 245′ is further disposed on the opposite side of the slit s2 with respect to the opening o2. As a result, a transistor having higher breakdown voltage can be provided.

Also in the high-voltage transistor according to the first embodiment, the contact electrode CS connected to a part of the gate electrode member portion 245 may be disposed on the opposite side of the slit s2 with respect to the opening o2. As a result, a transistor having higher breakdown voltage can be provided.

### Second Embodiment

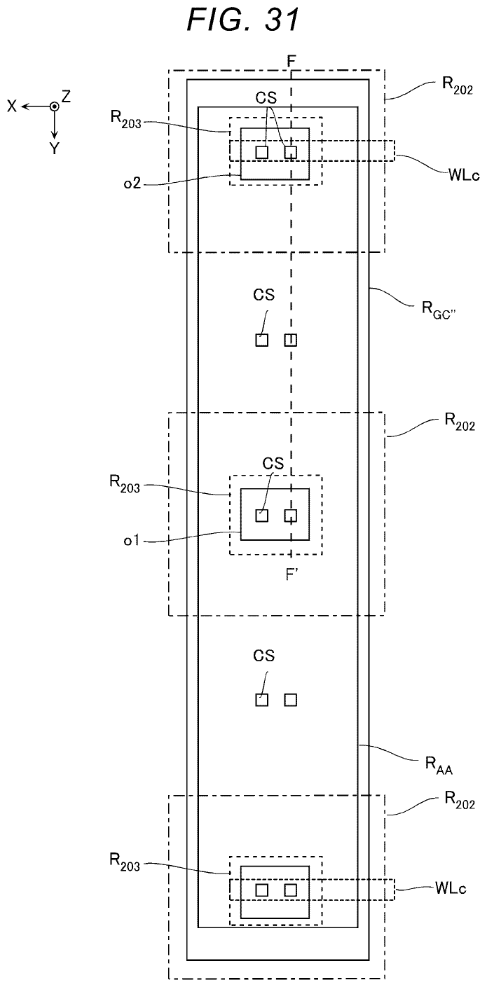

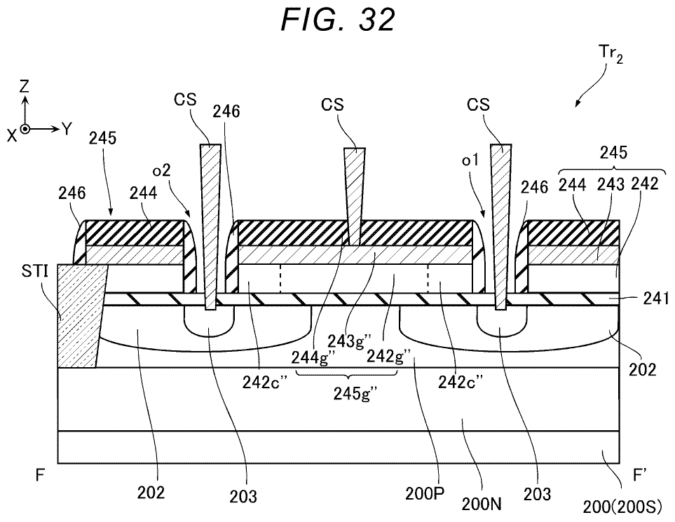

Next, a transistor Tr2 according to a second embodiment will be described with reference to FIGS. 31 and 32 and the like. FIG. 31 is a schematic plan view illustrating a structure of the transistor Tr2 according to the second embodiment. FIG. 32 is a schematic cross-sectional view illustrating the structure of the transistor Tr2 cut along a dotted line F-F′ in FIG. 31. The same components as in FIGS. 10 and 11 are represented by the same reference numerals and signs, and the description thereof will not be repeated.

The transistor Tr according to the first embodiment includes the slits s1 and s2 as described with reference to FIGS. 10 to 12. However, such configuration is merely an example. Hereinafter, a transistor not including the slits s1 and s2 will be described as the transistor Tr2 according to the second embodiment with reference to FIGS. 31 and 32. The transistor Tr2 is a high-voltage transistor used as the word line switch WLSW.

The transistor Tr2 according to the second embodiment is basically configured similarly to the word line switch WLSW according to the first embodiment. However, the transistor Tr2 according to the second embodiment includes a gate electrode 245g″ instead of the gate electrode 245g and the gate electrode member portions 245s and 245d.

As shown in FIG. 32, the gate electrode 245g″ is provided between the contact electrodes CS and faces the semiconductor substrate 200 with the gate insulating film 241 interposed therebetween.

More specifically, as shown in FIG. 32, the gate electrode 245g″ includes a gate electrode member 242g″, a gate electrode member 243g″, and a cap insulating layer 244g″. The gate electrode member 242g″ is provided on the upper surface of the gate insulating film 241 and is made of polycrystalline silicon (Si) or the like. The gate electrode member 243g″ is provided on an upper surface of the gate electrode member 242g″ and is made of tungsten (W) or the like. The cap insulating layer 244g″ is provided on an upper surface of the gate electrode member 243g″ and is made of silicon nitride (Si3N4) or the like. The gate electrode 245g″ further includes the sidewall insulating film 246 provided on side surfaces of the gate electrode member 242g″, the gate electrode member 243g″, and the cap insulating layer 244g″ in the X direction or the Y direction.

A part of the gate electrode member 242g″ faces a region functioning as a channel region between the two N− diffusion layers 202 adjacent in the Y direction on the upper surface of the semiconductor substrate 200. Such region of the gate electrode member 242g″ is, for example, an N+ layer containing an N-type impurity such as phosphorus (P). Another part of the gate electrode member 242g″ faces the N− diffusion layer 202. In FIG. 32, such region of the gate electrode member 242g″ is shown as a gate electrode member 242c″. An impurity concentration of the N-type impurity contained in the gate electrode member 242c″ is lower than an impurity concentration of the N-type impurity contained in the above-mentioned region of the gate electrode member 242g″ provided on the channel region.

### Effects of Second Embodiment and Others

Accordingly, the transistor Tr2 according to the second embodiment achieves the same effect as the high-voltage transistor according to the first embodiment.

### Other Embodiments

The semiconductor devices according to the first embodiment, the modification example, and the second embodiment are described above. However, the configurations described above are merely examples and can be appropriately modified.

For example, the gate electrode member portions 245s and 245d may be in a floating state and not electrically connected to the contact electrodes CS functioning as source electrodes and drain electrodes. Here, the gate electrode member portions 245 are also not electrically connected to the contact electrodes CS.

The technique described in the present specification is also applicable to configurations of semiconductor memory devices such as three-dimensional NOR flash memories. The technique described in the present specification is also applicable to configurations of semiconductor devices other than semiconductor storage devices.

### Others

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a semiconductor substrate;
a first contact electrode connected to the semiconductor substrate;
a second contact electrode separated from the first contact electrode and connected to the semiconductor substrate;
a gate electrode facing the semiconductor substrate between the first and second contact electrodes;
a third contact electrode on the gate electrode;
a first electrode member facing the semiconductor substrate between the first contact electrode and the gate electrode; and
a second electrode member facing the semiconductor substrate between the second contact electrode and the gate electrode, wherein
the gate electrode contains a first conductivity type impurity,
each of the first and second electrode members contains the first conductivity type impurity or a second conductivity type impurity that is different from the first conductivity type impurity, and
a concentration of the first conductivity type impurity or the second conductivity type impurity in the first and second electrode members is lower than a concentration of the first conductivity type impurity in the gate electrode.

2. The semiconductor device according to claim 1, wherein
a side surface of each of the first and second electrode members faces one of side surfaces of the gate electrode.

3. The semiconductor device according to claim 2, wherein
the first electrode member is electrically connected to the first contact electrode, and
the second electrode member is electrically connected to the second contact electrode.

4. The semiconductor device according to claim 2, wherein
the first and second electrode members are not electrically connected to any of the first, second, and third contact electrodes.

5. The semiconductor device according to claim 1, wherein
the gate electrode includes an electrode member that is connected to the first and second electrode members.

6. The semiconductor device according to claim 1, wherein
the gate electrode includes a first member made of polycrystalline silicon containing the first conductivity type impurity and a second member containing tungsten.

7. The semiconductor device according to claim 6, wherein
each of the first and second electrode members includes:
a third member made of polycrystalline silicon containing the first conductivity type impurity or the second conductivity type impurity and
a fourth member containing tungsten.

8. The semiconductor device according to claim 1, wherein
the gate electrode includes:
a first member made of polycrystalline silicon containing the first conductivity type impurity and
a silicide portion in which silicide is formed in a region of the first member including a contact portion coming into contact with the third contact electrode.

9. The semiconductor device according to claim 8, wherein
each of the first and second electrode members includes a member made of polycrystalline silicon containing the first conductivity type impurity or the second conductivity type.

10. The semiconductor device according to claim 1, wherein the first conductivity type impurity is an N-type impurity.

11. The semiconductor device according to claim 10, wherein
the first and second electrode members contain a P-type impurity as the second conductivity type impurity.

12. The semiconductor device according to claim 1, further comprising:
a first insulating film on one side surface of the gate electrode;
a second insulating film on another side surface of the gate electrode;
a third insulating film on one side surface of the first electrode member and contacting the first insulating film; and
a fourth insulating film on one side surface of the second electrode member and contacting the second insulating film.

13. The semiconductor device according to claim 12, further comprising:
a fifth insulating film on another side surface of the first electrode member and not contacting the first contact electrode; and
a sixth insulating film on another side surface of the second electrode member and not contacting the second contact electrode.

14. The semiconductor device according to claim 1, further comprising:
a gate insulating film extending along the semiconductor substrate, wherein
each of the first and second contact electrodes penetrates the gate insulating film, and
the gate electrode is on the gate insulating film.

15. The semiconductor device according to claim 1, wherein
the gate electrode includes a first member, a second member on the first member, and an insulating layer on the second member, and
the third contact electrode penetrates the insulating layer and contacts the second member.

16. A semiconductor device comprising:
a semiconductor substrate;
a first contact electrode connected to the semiconductor substrate;
a second contact electrode separated from the first contact electrode and connected to the semiconductor substrate;
a first gate electrode member facing the semiconductor substrate between the first and second contact electrodes;
a third contact electrode above the first gate electrode member;
a second gate electrode member facing the semiconductor substrate between the first contact electrode and the first gate electrode member, the second gate electrode member being connected to the first gate electrode member; and
a third gate electrode member facing the semiconductor substrate between the second contact electrode and the first gate electrode member, the third gate electrode member being connected to the first gate electrode member, wherein
the first gate electrode member contains a first conductivity type impurity,
each of the second and third gate electrode members contains the first conductivity type impurity or a second conductivity type impurity that is different from the first conductivity type impurity, and
a concentration of the first conductivity type impurity or the second conductivity type impurity in the second and third gate electrode members is lower than a concentration of the first conductivity type impurity in the first gate electrode member.

17. The semiconductor device according to claim 16, wherein
the second gate electrode member is electrically connected to the first contact electrode, and
the third gate electrode member is electrically connected to the second contact electrode.

18. The semiconductor device according to claim 16, wherein
the first gate electrode member is made of polycrystalline silicon containing the first conductivity type impurity.

19. The semiconductor device according to claim 18, further comprising:
a fourth gate electrode member extending on the first, second, and third gate electrode members and containing tungsten.

20. The semiconductor device according to claim 19, wherein the third contact electrode is connected to the fourth gate electrode member.
